(19) United States
(12) Patent Application Publication
(10) Pub. No.: US 2026/0206553 A1
(43) Pub. Date: Jul. 16, 2026

(54) Semiconductor Exfoliation Method

(71) Applicant: ThinSIC Inc, Santa Clara, CA (US)

(72) Inventors: Tirunelveli Subramaniam Ravi, San Jose, CA (US); Stephen Daniel Miller, San Jose, CA (US); Jeffrey Scott Pietkiewicz, San Jose, CA (US); Kelly Marie Moyers, Santa Clara, CA (US)

(73) Assignee: ThinSiC Inc., Santa Clara, CA (US)

(21) Appl. No.: 19/366,697

(22) Filed: Oct. 23, 2025

Related U.S. Application Data
(63) Continuation-in-part of application No. 19/229,238, filed on Jun. 5, 2025.
Application No. 19/229,238 is a continuation of application No. 17/857,018, filed on Jul. 3, 2022, now Pat. No. 12,400,914.

(51) Int. Cl. H10P 95/00; C30B 25/04; C30B 25/20; C30B 29/36; C30B 33/02; H10D 8/01; H10D 8/60; H10D 62/832; H10P 14/20

(52) U.S. Cl. CPC H10P 95/112; C30B 25/04; C30B 25/20; C30B 29/36; C30B 33/02; H10D 8/051; H10D 8/60; H10D 62/8325; H10P 14/2904; H10P 14/2925; H10P 14/3408

(57) ABSTRACT

A method of forming two semiconductor wafers from a single reuseable semiconductor wafer is disclosed. The two semiconductors can be used for wafer processing or to generate new semiconductor wafers. A patterned layer is formed in a silicon carbide (SIC) substrate. The patterned layer includes a heatable material. An epitaxial layer is grown by epitaxial lateral overgrowth overlying the patterned layer to form a surface overlying the SiC substrate. At least one epitaxial layer by epitaxial vertical overgrowth is grown overlying the epitaxial layer. The heatable material is heated by one or more lasers to fracture or weaken the patterned layer. The epitaxial layer and the at least one epitaxial layer comprises a SiC epitaxial substrate. The SiC substrate is separated from the SiC epitaxial substrate.

### FIELD

This invention relates to semiconductor substrates and, in particular to forming a semiconductor substrate comprising one or more epitaxial layers.

### BACKGROUND

The use of wide bandgap (WBG) semiconductors has increased dramatically in recent years in power electronics. Their ability to operate efficiently at higher voltages, powers, temperatures, and switching frequencies has enabled reduced cooling requirements, lower part counts, and the use of smaller passive components. WBG-based power electronics can further reduce the footprint and potentially the system cost of various renewable energy electrical equipment such as motor drivers and inverters.

Among the WBG semiconductors for power electronics, Silicon Carbide (SIC) is now increasingly used for high voltage drivers (>1200V) whereas Gallium Nitride (GaN) has been experiencing increased use in both higher power and higher frequency applications. However, unlike silicon, the cost of a final device for WBG semiconductor devices is dominated by the cost of the materials. The materials include the substrate and the active layer grown by Epitaxy. The substrate by itself contributes to over half of the cost of a finished WBG semiconductor device.

From the substrate standpoint, 4H-Silicon carbide (SIC) Single Crystal Substrates have been used for both SiC and GaN devices since SiC and GaN epitaxial layers can be grown with reduced defects on SiC substrates. The GaN substrate, on the other hand, is very expensive to grow defect free and has not kept up with scaling size increases afforded with SiC substrates. While the SiC substrate quality has dramatically improved in the recent years, the cost has not come down since substrate fabrication is a complex process starting with vapor phase ingot growth followed by ingot cropping, then wire sawing of individual wafers, and finally grinding and polishing of the substrate, and as of now, there has been no proven practical method to eliminate any of these foregoing steps. As a semiconductor substrate for WBG semiconductors is being produced and devices that use high currents are fabricated, defects play a larger role and are magnified because die sizes are larger, and any defect will contribute to more significant yield loss and potential lower reliability. Therefore, to maximize die yield, any cost reduction activity regarding the substrate is paramount while also maintaining low defect densities in the active device epitaxial layer. The effect of material defects is magnified due to larger die sizes which would therefore incorporate more material defects which would, in each contribute to more significant yield loss and potentially lower reliability. Therefore, to maximize die yield and cost reduction activity regarding the substrate while also maintaining low defect densities in the active epitaxial layers is paramount.

Accordingly, it is desirable to provide methods to manufacture WBG semiconductors that overcome the thin substrate limitation and reduce the contribution of the substrate to the final die with minimal effect to the yield or performance parameters of the final WBG semiconductor.

### BRIEF DESCRIPTION OF THE DRAWINGS

Various features of the system are set forth with particularity in the appended claims. The embodiments herein can be understood by reference to the following description, taken in conjunction with the accompanying drawings, in which:

FIG. 1 is an illustration of a reusable silicon carbide substrate in accordance with an example embodiment;

FIG. 2 is an illustration of a layer formed overlying the silicon carbide substrate in accordance with an example embodiment;

FIG. 3 is an illustration of a hard mask layer deposited overlying a carbon layer on the silicon carbide substrate, in accordance with an example embodiment;

FIG. 4 is an illustration of a plurality of openings formed in the hard mask layer in accordance with an example embodiment;

FIG. 5 is an illustration of a plurality of trenches formed in a carbon layer in accordance with an example embodiment;

FIG. 6 is an illustration where the patterned hard mask is removed forming a plurality of trenches in accordance with an example embodiment;

FIG. 7 is an illustration of an epitaxial layer formed overlying the surface of patterned carbon regions in accordance with an example embodiment;

FIG. 8 is an illustration of silicon carbide substrate patterned to form a plurality of trenches 8 and a plurality of silicon carbide pillars in accordance with an alternate example embodiment;

FIG. 9 is an illustration of a silicon carbide substrate patterned with plurality of trenches filled with a carbon layer partially filling the plurality of trenches in accordance with the alternate embodiment;

FIG. 10 is an illustration of an epitaxial layer formed over a silicon carbide substrate in accordance with the alternate embodiment;

FIG. 11 is an illustration of a silicon carbide substrate patterned with a plurality of trenches having a plurality of micro-voids in accordance with an alternate embodiment;

FIG. 12 is an illustration of a silicon carbide substrate patterned with a plurality of trenches over a plurality of micro-voids filled with a carbon layer partially filling the plurality of trenches and completely filling the plurality of micro-voids in accordance with the alternate embodiment;

FIG. 13 is an illustration of an epitaxial layer over silicon carbide substrate 100 patterned in accordance with the alternate embodiment.

FIG. 14 is an illustration of an epitaxial layer formed overlying an epitaxial layer in accordance with an example embodiment;

FIG. 15 is an illustration of an epitaxial layer being doped to lower resistivity in accordance with an example embodiment;

FIG. 16 is an illustration of a dielectric isolation layer deposited on ohmic contact region on an epitaxial layer in accordance with an example embodiment;

FIG. 17 is an illustration of the dielectric isolation layer being patterned in accordance with an example embodiment;

FIG. 18 is an illustration of a metal contact layer configured to form an electrode of a Schottky Diode in accordance with an example embodiment;

FIG. 19 is an illustration of a carrier wafer temporarily coupled to a reusable silicon carbide substrate with a Schottky Barrier Diode in accordance with an example embodiment;

FIG. 20 is an illustration of a reusable silicon carbide substrate with a Schottky Barrier Diode temporarily coupled to the carrier wafer undergoing an exfoliation process using a laser in accordance with an example embodiment;

FIG. 21 is an illustration of a reusable silicon carbide substrate being separated from a Schottky Barrier Diode in accordance with an example embodiment;

FIG. 22 is an illustration of a portion of silicon carbide substrate with a Schottky Barrier Diode coupled to a carrier wafer after exfoliation in an exfoliation tool in accordance with an example embodiment;

FIG. 23 is an illustration of a portion of silicon carbide substrate with a Schottky Barrier Diode coupled to a carrier wafer after removal from the exfoliation tool in accordance with an example embodiment;

FIG. 24 is an illustration of a silicon carbide substrate with a Schottky Barrier Diode coupled to a carrier wafer after removal by the exfoliation tool in accordance with an example embodiment;

FIG. 25 is an illustration of a metal layer deposited on a surface of an epitaxial layer in accordance with an example embodiment;

FIG. 26 is an illustration of a silicon carbide substrate with a Schottky Barrier Diode separated from a carrier wafer in accordance with an example embodiment;

FIG. 27 is an illustration of a remaining silicon carbide substrate separated from a silicon carbide substrate after the exfoliation process in accordance with an example embodiment;

FIG. 28 is an illustration of further processing of the remaining silicon carbide substrate separated from a silicon carbide substrate after the exfoliation process in accordance with an example embodiment;

FIG. 29 is an illustration of a block diagram of an exfoliation process in accordance with an example embodiment;

FIG. 30 is an illustration of a block diagram of an exfoliation process in accordance with an example embodiment;

FIG. 31 is an illustration of a silicon carbide substrate in accordance with an example embodiment;

FIG. 32 is an illustration of a hard mask layer that is deposited overlying the silicon carbide substrate, in accordance with an example embodiment;

FIG. 33 is an illustration of a patterned hard mask in accordance with an example embodiment;

FIG. 34 is an illustration of a pattern etched in the silicon carbide substrate, in accordance with an example embodiment;

FIG. 35 is an illustration of a patterned layer that is formed in accordance with an example embodiment;

FIG. 36 is an illustration of a layer of heatable material and a protective layer 3620 in accordance with an example embodiment;

FIG. 37 is an illustration of an epitaxial layer grown overlying the patterned layer in accordance with an example embodiment;

FIG. 38 is an illustration of a surface of the epitaxial layer in accordance with an example embodiment;

FIG. 39 is an illustration of an epitaxial layer grown overlying an epitaxial layer in accordance with an example embodiment;

FIG. 40 is an illustration of a epitaxial silicon carbide substrate formed in accordance with an example embodiment;

FIG. 41 is an illustration of a reusable silicon carbide substrate in accordance with an example embodiment;

FIG. 42 is an illustration of semiconductor devices formed in the reusable silicon carbide substrate in accordance with an example embodiment;

FIG. 43 is an illustration of a silicon carbide substrate in accordance with an example embodiment;

FIG. 44 is an illustration of a reclaimed silicon carbide substrate in accordance with an example embodiment;

FIG. 45 shows a block diagram for the formation of a reusable silicon carbide wafer in accordance with an example embodiment;

FIG. 46 is an illustration of a silicon carbide substrate with a patterned layer in accordance with an example embodiment;

FIG. 47 is an illustration of a silicon carbide epitaxial layer grown overlying the patterned layer in accordance with an example embodiment;

FIG. 48 is an illustration of a silicon carbide epitaxial layer grown overlying a silicon carbide epitaxial layer in accordance with an example embodiment;

FIG. 49 is an illustration of a silicon carbide epitaxial layer formed overlying a silicon carbide epitaxial layer in accordance with an example embodiment;

FIG. 50 is an illustration of a silicon carbide substrate formed by exfoliation in accordance with an example embodiment;

FIG. 51 is an illustration of a reusable epitaxial silicon carbide substrate in accordance with an example embodiment;

FIG. 52 is an illustration of a reusable epitaxial silicon carbide substrate in accordance with an example embodiment;

FIG. 53 is an illustration of a plurality of semiconductor devices formed in the reusable epitaxial silicon carbide substrate in accordance with an example embodiment;

FIG. 54 is an illustration of a silicon carbide substrate in accordance with an example embodiment.

FIG. 55 is an illustration of a reclaimed silicon carbide substrate in accordance with an example embodiment; and

FIG. 56 shows the block diagram for the formation of a reusable silicon carbide wafer in accordance with an example embodiment.

### DETAILED DESCRIPTION

The following description of embodiment(s) is merely illustrative in nature and is in no way intended to limit the invention, its application, or uses.

For simplicity and clarity of the illustration(s), elements in the figures are not necessarily to scale, are only schematic, are non-limiting, and the same reference numbers in different figures denote the same elements, unless stated otherwise.

Additionally, descriptions and details of well-known steps and elements are omitted for simplicity of the description. Notice that once an item is defined in one figure, it may not be discussed or further defined in the following figures.

The terms “first”, “second”, “third” and the like in the Claims or/and in the Detailed Description are used for distinguishing between similar elements and not necessarily for describing a sequence, either temporally, spatially, in ranking or in any other manner. It is to be understood that the terms so used are interchangeable under appropriate circumstances and that the embodiments described herein are capable of operation in other sequences than described or illustrated herein.

Processes, techniques, apparatus, and materials as known by one of ordinary skill in the art may not be discussed in detail but are intended to be part of the enabling description where appropriate.

While the specification concludes with claims defining the features of the invention that are regarded as novel, it is believed that the invention will be better understood from a consideration of the following description in conjunction with the drawing figures, in which like reference numerals are carried forward.

The current invention is described with an example embodiment of the fabrication of a Schottky Barrier Diode (SBD) using a silicon carbide wafer as the starting substrate. The starting substrate used is a semiconductor substrate that can be used as a reusable semiconductor substrate multiple times for fabrication of semiconductor devices. Alternatively, other devices such as transistors, passive devices, or power transistors can be formed using the described process flow. While silicon carbide substrate is used in the example embodiment, the invention can be implemented in other semiconductor substrates such as gallium nitride, gallium arsenide, indium phosphide, silicon, silicon on insulator (SOI) among others. In addition, the invention may be used in other semiconductor devices such as photonic devices, lasers, light emitting diodes, RF devices, among others.

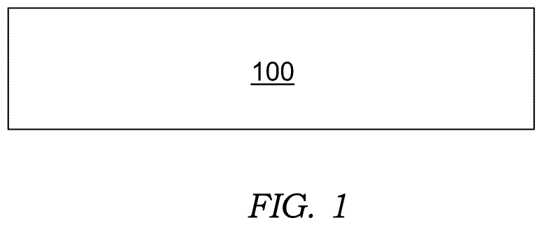

FIG. 1 is an illustration of a reusable silicon carbide substrate 100 in accordance with an example embodiment. Silicon carbide substrate 100 is used as a starting material for the fabrication of the Schottky Barrier Diode. In one embodiment, silicon carbide substrate 100 is a crystalline 4H silicon carbide wafer with a preferred crystalline orientation of <0001> with an offcut towards <1120> of 4 degrees. In one embodiment, a thickness of silicon carbide substrate 100 is in the range of 300-400 microns. In one embodiment, silicon carbide substrate 100 may be a single side polished or double side polished wafer and can be considered as the parent wafer, for considerations that are described in subsequent process steps in the implementation of the current invention. In one embodiment, silicon carbide substrate 100 is the basic platform on which the example embodiment is implemented to support the process flow in accordance with the current invention. Silicon carbide substrate 100 is a reusable semiconductor substrate that is used for fabrication of semiconductor devices multiple times on the same substrate, in accordance with the current invention.

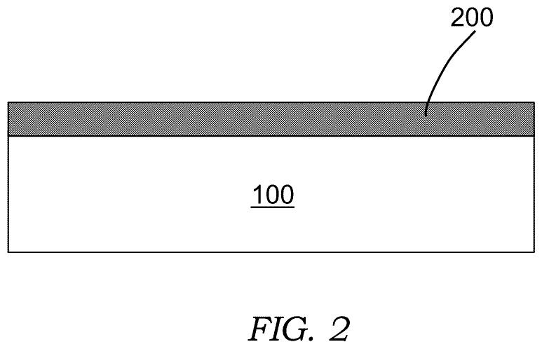

FIG. 2 is an illustration of a layer 200 formed overlying silicon carbide substrate 100 in accordance with an example embodiment. In one embodiment layer 200 comprises a carbon material and is formed on a surface of silicon carbide substrate 100. In one embodiment, layer 200 is formed on the surface of silicon carbide substrate 100 using a variety of methods. In one embodiment, layer 200 is formed on the surface of silicon carbide substrate 100 using sputtered carbon. In another embodiment, layer 200 is deposited using CVD (Chemical Vapor Deposition) or PVD (Physical Vapor Deposition) among other techniques.

In another embodiment, layer 200 is formed on the surface of silicon carbide substrate 100 by depositing a polymer layer and then converting the polymer layer into a carbon layer using pyrolysis. In one embodiment, the polymer layer is composed of Parylene. Parylene (trade name for poly p-xylylene) is a semicrystalline thermoplastic polymer deposited using CVD (Chemical Vapor Deposition). Parylene C is one version of parylene which is a chlorinated poly para-xylylene polymer and is deposited using CVD (Chemical Vapor Deposition) to form a conformal coating. Parylene C deposition consists of heating a solid, granular material called dimer under vacuum to vaporize into a dimeric gas in a temperature range of (100-150)° C. The dimeric gas is then pyrolyzed to cleave the dimer into its monomeric form. The monomer gas is then used in a vacuum chamber at room temperature to deposit conformally on all surfaces of the samples inside a vacuum chamber as a polymer film. In one embodiment, silicon carbide substrate 100 is coated with polymer layer of Parylene C conformally. The thickness of Parylene C is in a range of 500 nanometers (nm) to several micrometers (um). The deposited Parylene C is converted into layer 200 which is a carbon layer using a process of pyrolysis. The pyrolysis of Parylene C into carbon is done in an inert environment. The pyrolysis of Parylene C converts the Parylene C into a carbon layer which may be amorphous or polycrystalline. In one embodiment, the temperature for pyrolysis is between (600-1200)° C. and the inert environment is nitrogen or a forming gas (nitrogen and hydrogen) among others. In one embodiment, to account for the shrinkage of the Parylene C during the pyrolysis process, multiple layers of Parylene C are deposited and converted to carbonized layer to achieve the target thickness of carbon layer 200.

In one embodiment, the polymer layer is composed of photoresist. The photoresist used as the polymer may be of positive or negative polarity. In one embodiment, polymer photoresist layer is spin coated on the surface of silicon carbide substrate 100. Photoresist polymer layer may also be spray coated on surface of silicon carbide substrate 100. In one embodiment, after the deposition of the polymer photoresist it is soft baked to drive out solvents. Soft baking polymer photoresist means that it is heated to a temperature in the range of (90-100)° C. in an inert environment such as nitrogen to drive out solvents. Multiple layers of polymer photoresist may be used to achieve the desired thickness of polymer photoresist.

Polymer photoresist layer deposited on surface of silicon carbide substrate 100 is converted to carbon layer 200 by process of pyrolysis. Pyrolysis of polymer photoresist layer consists of thermal treatment in an inert environment to form carbon layer 200. Pyrolysis of polymer photoresist layer into carbon layer 200 can comprise multiple intermediate thermal treatments. In one embodiment, polymer photoresist layer is baked in nitrogen environment at 90° C. (typically called a soft bake), followed by bake at 115° C. (typically called a hard bake) in the nitrogen environment. Hard baked polymer photoresist layer is then cured at 450° C. in the nitrogen environment and then pyrolyzed in a furnace in the nitrogen environment at (800-1200)° C. to convert the polymer photoresist layer to carbon layer 200. In another embodiment, a forming gas (nitrogen and hydrogen) is used for the pyrolysis of polymer photoresist layer to carbon layer 200.

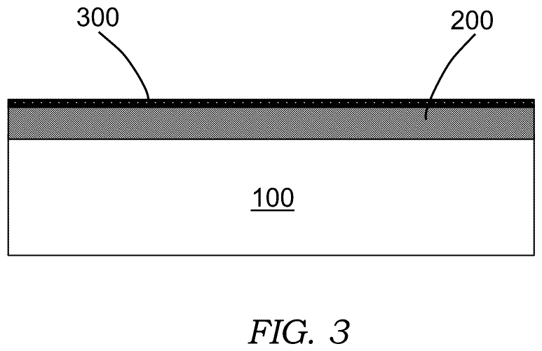

FIG. 3 is an illustration of a hard mask layer 300 deposited overlying carbon layer 200 on silicon carbide substrate 100 in accordance with an example embodiment. In one embodiment, hard mask layer 300 is deposited on a surface of carbon layer 200. Hard mask layer 300 is deposited using techniques such as CVD (Chemical Vapor Deposition), LPCVD (low pressure chemical vapor deposition), PECVD (Plasma Enhanced Chemical Vapor Deposition), APCVD (Atmospheric Pressure Chemical Vapor Deposition), SACVD (Sub Atmospheric Chemical Vapor Deposition), PVD (Physical Vapor Deposition), or ALD (Atomic layer Deposition). In the example implementation, hard mask layer 300 is composed of Al₂O₃ deposited using ALD (Atomic Layer Deposition) The thickness of hard mask layer 300 is determined by the specific requirements of the implementation and is well known to those skilled in the art and is the range of 20-300 nm.

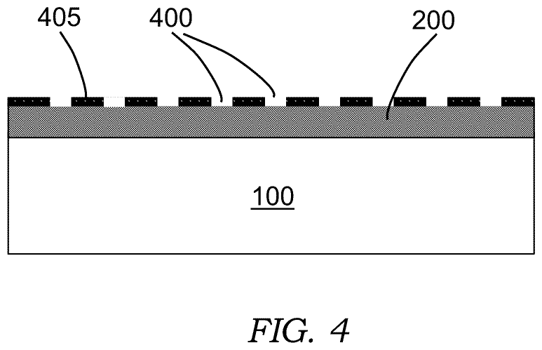

FIG. 4 is an illustration of a plurality of openings 400 formed in hard mask layer 300 of FIG. 3 in accordance with an example embodiment. In one embodiment, the process steps disclosed herein below will lead to the formation of a device in substrate 100 and more specifically a Schottky Barrier Diode as an example semiconductor device. Hard mask layer 300 of FIG. 3 deposited over the carbon layer 200 over surface of substrate 100 is patterned to subsequently support the formation of plurality of openings 400. In one embodiment, the surface of carbon layer 200 is exposed by removal of hard mask layer 300 to form plurality of openings 400. Plurality of openings 400 are formed in hard mask layer 300 using methods of lithography and etching common to the semiconductor industry. Patterned hard mask 405 is left in areas to protect portions of carbon layer 200 from being etched. The shape of plurality of openings 400 are determined by the requirements of epitaxial growth in subsequent steps in the implementation of the example embodiment. In one embodiment, plurality of openings 400 may be in the shape of squares or rectangles. In another embodiment, plurality of openings 400 may be in the shape of triangles, hexagons or diamonds. In another embodiment, plurality of openings 400 may be in the shape of stripes which may be horizontal, vertical, or sloped at a diagonal angle. In one embodiment, the size of plurality of openings 400 may be in the range of (20-500) nm and determined by the requirements of epitaxial overgrowth in the subsequent steps of fabrication of the example device. In one embodiment, spacing between adjacent openings of plurality of openings 400 is determined by the requirements of epitaxial overgrowth in the subsequent steps of fabrication of the example device and can be in the range of 500 nm to 5 micrometers. Plurality of openings 400 are generated on a surface of hard mask layer 300 of FIG. 3 by using lithography techniques that are well known to those skilled in the art. In one embodiment, plurality of openings 400 are implemented using optical lithography using UV, DUV or EUV. In another embodiment, plurality of openings 400 are implemented using an electron beam direct write technique. In yet another embodiment, plurality of openings 400 are implemented using Nano-Imprint Lithography (NIL).

In one example embodiment, plurality of openings 400 are implemented by first coating a surface of hard mask layer 300 with a photosensitive layer of photoresist, which may be positive or negative in its chemistry. In the example embodiment, positive photoresist is used in coating the surface of hard mask layer 300. An optical tool called a stepper is used to transfer the pattern of openings on to the positive photoresist layer using chemistries that are well known to those skilled in the art. The choice of the photoresist layer, thickness of the photoresist layer, the exposure and develop times for the subsequent chemical steps are well known to those skilled in the art and determined by the requirements of accurate pattern transfer from the photoresist layer to hard mask layer 300 to subsequently form plurality of openings 400. The stepper transfers the pattern of plurality of openings 400 to cover the surface of hard mask layer 300 over carbon layer 200 over silicon carbide substrate 100.

After the pattern transfer is completed using lithography, the next step is the patterning of hard mask layer 300 using etching techniques to selectively remove the hard mask layer 300 of FIG. 3 overlying carbon layer 200 on silicon carbide substrate 100 leaving patterned hard mask 405 on carbon layer 200 over substrate 100. The selective removal of hard mask layer 300 to form patterned hard mask 405 may use Reactive lon Etching (RIE). Different gases may be used to form a plasma to selectively remove the portions of hard mask layer 300 exposed by the patterned photoresist. The choice of gases for the RIE is determined by hard mask layer 300 used in the implementation. In the example embodiment, with Al₂O₃ layer used as hard mask layer 300, fluorine-based chemistries such as SF₆, CF₄, CHF₃, and other gases may be used in the RIE. Accordingly, in the example embodiment with Al₂O₃ layer as hard mask layer 300, plurality of openings 400 are etched in hard mask layer 300 using a fluorine-based chemistry that exposes the surface of carbon layer 200 in plurality of openings 400. Patterned hard mask 405 remains in areas overlying carbon layer 200 to protect or mask the surface of carbon layer 200 from etching.

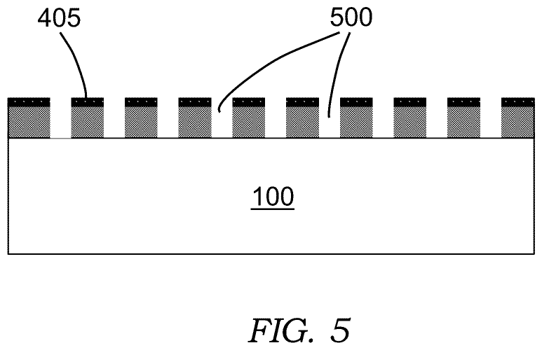

FIG. 5 is an illustration of a plurality of trenches 500 formed in carbon layer 200 in accordance with an example embodiment. Plurality of trenches 500 expose a surface of silicon carbide substrate 100 after etching carbon layer 200 exposed by plurality of openings 400 from FIG. 4. Thus, the exposed surface of carbon layer 200 over silicon carbide substrate 100 in plurality of openings 400 is etched to form plurality of trenches 500 in FIG. 5 using RIE (Reactive lon Etching). In one embodiment, carbon layer 200 is etched using patterned hard mask 405 to form plurality of trenches 500 with an aspect ratio that is determined by the requirements of epitaxial growth in subsequent processing of the example device. Thus, plurality of openings 400 are etched in the carbon layer 200 to expose the surface of silicon carbide substrate 100 to form plurality of trenches 500. The depth of plurality of trenches 500 is dependent on the thickness of carbon layer 200 and may be in the range of 500 nm to 3 micrometers. An oxygen plasma with fluorine chemistry or argon may be used for etching carbon layer 200 using patterned hard mask 405. An inductively coupled plasma (ICP) with high density may also be used to form plurality of trenches 500 using patterned hard mask 405 over carbon layer 200 over silicon carbide substrate 100. After plurality of trenches 500 are formed by etching the exposed surfaces of plurality of openings 400 in carbon layer 200 over silicon carbide substrate 100, the photoresist is removed using resist stripping techniques well known to those skilled in the art. The resist stripping technique may use dry etching or wet etching or a combination of dry and wet stripping techniques.

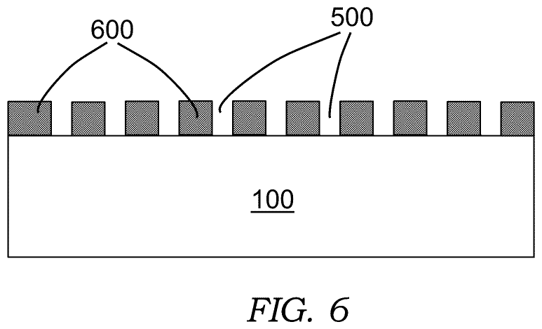

FIG. 6 is an illustration of an example embodiment where patterned hard mask 405 is removed forming a plurality of trenches 500 in accordance with an example embodiment. FIG. 6 further illustrates plurality of patterned carbon regions 600 formed overlying silicon carbide substrate 100. Patterned hard mask 405 of FIG. 5 is removed using wet etching, dry etching or a combination of wet etching and dry etching, depending on hard mask layer 300. In an example embodiment, hard mask layer 300 of FIG. 3 comprises Al₂O₃ that is etched using dilute BOE (Buffered Oxide Etch). Silicon carbide substrate 100 with plurality of patterned carbon regions 600 and plurality of trenches 500 is then cleaned in preparation for the next step in the fabrication of the example device. In one embodiment, the pattern of plurality of trenches 500 are shaped as triangles or hexagons to expose (1120) or equivalent crystal planes since these orientations facilitate high quality epitaxial overgrowth with low defect density in subsequent processing steps in accordance with the current invention.

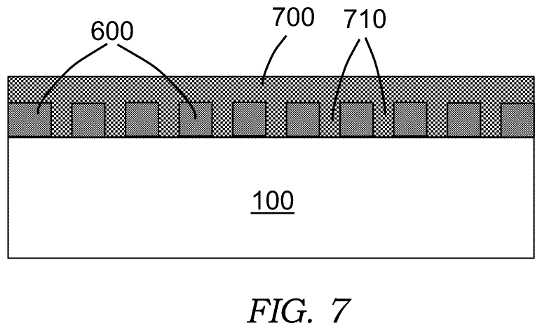

FIG. 7 is an illustration of an epitaxial layer 700 formed overlying the surface of patterned carbon regions 600 in accordance with an example embodiment. In one embodiment, epitaxial layer 700 is a silicon carbide epitaxial layer formed over patterned carbon regions 600 and coupling to silicon carbide substrate 100. Epitaxial layer 700 may be a N+ heavily doped layer forming a buffer epitaxial layer. In one embodiment, epitaxial layer 700 forms a plurality of silicon carbide pillars 710 between the patterned carbon regions 600 by epitaxial growth of silicon carbide from surface of silicon carbide substrate 100 in plurality of openings 500 from FIG. 6.

In general, epitaxial layer 700 is formed on silicon carbide substrate 100 with patterned carbon regions 600 overlying silicon carbide substrate 100 in a silicon carbide epitaxial reactor. In the epitaxial reactor, silicon carbide grows with the crystalline orientation of exposed silicon carbide substrate 100 in plurality of openings 500 from FIG. 6. In the epitaxial reactor, silicon carbide grows vertically as well as laterally with patterned carbon regions 600 inhibiting the epitaxial growth with growth conditions that are well known to those skilled in the art. The silicon carbide forms array of silicon carbide pillars 710 due to the vertical growth of silicon carbide and then forms epitaxial layer 700 when it grows laterally. Note that silicon carbide pillars 710 corresponds to silicon carbide between adjacent patterned carbon regions 600. Once above patterned carbon regions 600, the silicon carbide grows as a uniform layer.

The lateral fronts of the epitaxial regions of silicon carbide epitaxial layer 700 merge due to epitaxial lateral overgrowth (ELO) or merged epitaxial lateral overgrowth (MELO). The process of epitaxial crystal growth is used to form a single crystal layer of silicon carbide over patterned carbon regions 600 forming epitaxial layer 700 with silicon carbide pillars 710. In the example embodiment, epitaxial layer 700 is an epitaxial layer of silicon carbide. This method of ELO or MELO over the regions of patterned carbon 600 enables the formation of epitaxial layer 700 with low defect density which is mechanically supported by patterned carbon regions 600 and plurality of silicon carbide pillars 710. Silicon carbide substrate 100 with patterned carbon regions 600 and plurality of silicon carbide pillars 710 below epitaxial layer 700 forms a plane where epitaxial layer 700 can be exfoliated from substrate 100 in subsequent process steps.

The patterned carbon regions 600 along with plurality of pillars 710 enables the formation of epitaxial layer 700 as a single crystal silicon carbide layer by ELO or MELO. This plane of separation comprises patterned carbon regions 600 and plurality of pillars 710. In one embodiment, epitaxial layer 700 is grown in an epitaxial reactor using CVD (Chemical Vapor Deposition) epitaxial growth processes or by modified bulk crystal growth processes such as high Temperature CVD or by Physical Vapor Transport (PVT). The exfoliation process of separating substrate 100 from epitaxial layer 700 will be disclosed in detail herein below.

Patterned carbon regions 600 is compatible with the epitaxial growth process since carbon is incorporated in the silicon carbide crystalline structure during the epitaxial growth where gases such as acetylene (C₂H₂) is used in the epitaxial reactor along with other process gases such as DCS (Dichlorosilane), TCS (trichlorosilane), silane among other process gases. Patterned carbon regions 600 may be amorphous or polycrystalline depending on the method of forming the carbon layer 200 from FIG. 2 and is capable of withstanding high temperature processing of the silicon carbide devices formed above epitaxial layer 700 in subsequent process steps. In addition, carbon has a Young's modulus of 70 GPa compared to 700 GPa of singe crystal silicon carbide.

By appropriate design of mechanical and thermal consideration of patterned carbon regions 600 with plurality of silicon carbide pillars 710, the forces required for exfoliation of single crystal silicon carbide epitaxial layer 700 may be tailored to be optimized such that the entire structure can withstand the thermal and mechanical processes during subsequent device formation steps while also being able to be separated by the exfoliation process in the plane of the patterned carbon regions 600 with plurality of silicon carbide pillars 710. In the example embodiment, epitaxial layer 700 comprises of N+4H Silicon Carbide and can be of a thickness of about 5-20 micrometers. In another embodiment, P+ silicon carbide can be used for epitaxial layer 700. The doping of epitaxial layer 700 is high enough to provide an ohmic contact for the silicon carbide device formed on epitaxial layer 700 during subsequent processing steps. Patterned carbon regions 600 inhibits the growth of silicon carbide epitaxial layer over it while enabling the lateral growth of silicon carbide from plurality of silicon carbide pillars 710 that grow from surface of reusable silicon carbide substrate 100 and also forms a portion of the plane where exfoliation is initiated in a later stage of the invention, as described in more detail in subsequent processing steps.

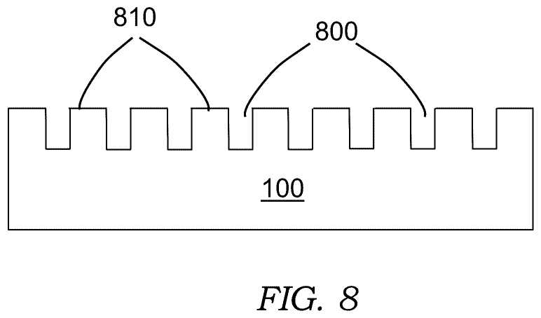

FIG. 8 is an illustration of silicon carbide substrate 100 patterned to form a plurality of trenches 800 and a plurality of silicon carbide pillars 810 in accordance with an alternate example embodiment. In one embodiment, pattern of plurality of trenches 800 is formed by coating silicon carbide substrate with a hard mask layer for patterning and etching. The hard mask layer used for patterning of trenches 800 may be composed of one or more layers. In one embodiment, the hard mask layer is composed of LPCVD Silicon Nitride coated with LPCVD silicon oxide. The hard mask layers are patterned using photoresist and optical lithography and etched using reactive ion etching (RIE). In one embodiment, hard mask layers of silicon nitride and silicon oxide are patterned using RIE using fluorine chemistry. After the patterning and etching of the hard mask layers, silicon carbide substrate 100 is etched using Reactive lon Etching using a fluorine chemistry to form plurality of trenches 800 and leaving plurality of silicon carbide pillars 810. Inductively Coupled Plasma (ICP) may also be used to etch silicon carbide substrate 100. After etching of plurality of trenches 800 and formation of plurality of silicon carbide pillars 810, hard mask layers are stripped using wet etching, dry etching or a combination of wet and dry etching. The aspect ratio of the plurality of pillars of silicon carbide may be between 2-10.

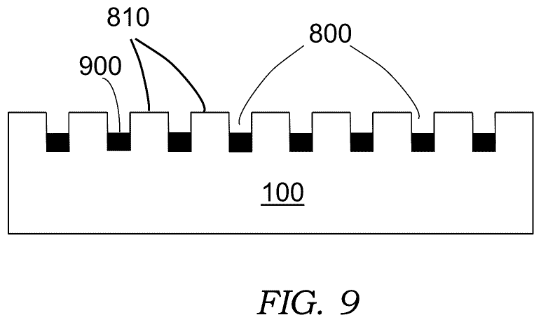

FIG. 9 is an illustration of silicon carbide substrate 100 patterned with plurality of trenches 800 filled with a carbon layer 900 partially filling plurality of trenches 800 in accordance with the alternate embodiment. Carbon layer 900 partially filling plurality of trenches 800 can be formed by sputter deposition of a carbon film on the surface of silicon carbide substrate 100 patterned with a plurality of trenches 800 and partially filled with carbon layer 900 by blanket etching of carbon film deposited on surface of silicon carbide substrate 100. Carbon layer 900 is removed from surfaces of plurality of silicon carbide pillars 810. In one embodiment, carbon layer 900 may be formed by deposition of a polymer on surface of silicon carbide substrate 100, etching back from top of plurality of silicon carbide pillars 810 and pyrolysis of polymer layer to form carbon layer 900 partially filling plurality of trenches 800. Polymer layer used for pyrolysis may be deposited by CVD (Chemical Vapor Deposition), PVD (Physical Vapor Deposition), spin coating, spray coating among other techniques.

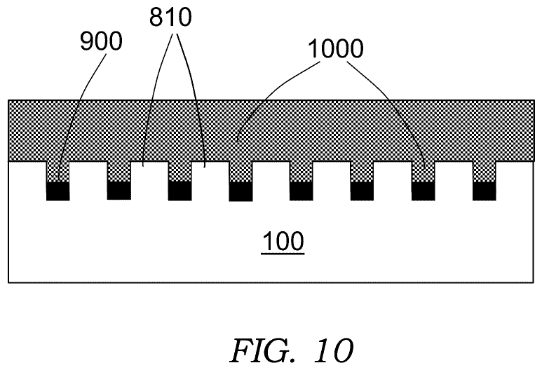

FIG. 10 is an illustration of an epitaxial layer 1000 formed over silicon carbide substrate 100 in accordance with the alternate embodiment. In one embodiment, epitaxial layer 1000 is a silicon carbide epitaxial layer forming a buffer epitaxial layer with low defect density. Epitaxial layer 1000 is formed by placing silicon carbide substrate 100 with plurality of trenches 800 from FIG. 9 partially filled with carbon layer 900 in a silicon carbide epitaxial reactor with epitaxial growth of silicon carbide using ELO (Epitaxial Lateral Overgrowth) or MELO (Merged Epitaxial Lateral Overgrowth) to form a single crystal epitaxial layer 1000. In the example, single crystal epitaxial layer 1000 overlies silicon carbide substrate 100, carbon layer 900, and plurality of pillars 810.

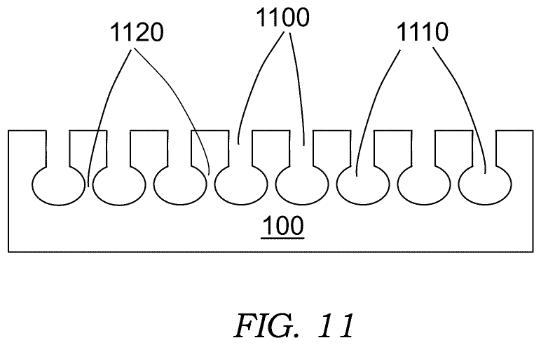

FIG. 11 is an illustration of silicon carbide substrate 100 patterned with a plurality of trenches 1100 having a plurality of micro-voids 1110 in accordance with an alternate embodiment. In one embodiment, a pattern corresponding to plurality of trenches 1100 is formed by coating silicon carbide substrate with a hard mask layer for patterning and etching. Hard mask layer used for patterning of plurality of trenches 1100 may be composed of one or more layers. In one embodiment, the hard mask layer is composed of LPCVD Silicon Nitride. The hard mask layer is patterned using photoresist and optical lithography and etched using reactive ion etching (RIE). In one embodiment, the hard mask layer of silicon nitride is patterned using RIE with a fluorine chemistry.

After the patterning and etching of the hard mask layers, silicon carbide substrate 100 is etched using Reactive lon Etching with the fluorine chemistry to form plurality of trenches 1100. Inductively Coupled Plasma (ICP) may also be used to etch silicon carbide substrate 100. After etching of plurality of trenches 1100, a conformal layer of a spacer layer is deposited and etched to form spacers in the walls of trenches 1100. The plurality of micro-voids 1110 are then etched in silicon carbide substrate 100 using isotopic etching chemistry below plurality of trenches 1100. In one embodiment, plurality of micro-voids are wider than the plurality of trenches 1100 and form plurality of pillars 1120. Plurality of pillars 1120 correspond to the silicon carbide between adjacent micro-voids of plurality of micro-voids 1110. After forming of trenches 1100 with plurality of micro-voids 1110 below plurality of trenches 1100 and leaving plurality of pillars 1120 in silicon carbide substrate 100, the hard mask layer and spacer layer is removed using wet chemistry. If the hard mask layer and spacer layer is silicon nitride, hot phosphoric acid is used for the removal of hard mask layer and spacer layer.

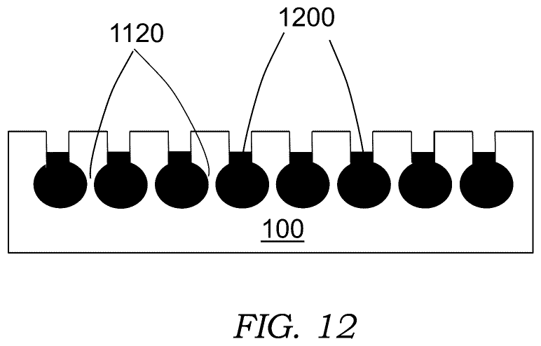

FIG. 12 is an illustration of silicon carbide substrate 100 patterned with a plurality of trenches 1100 over a plurality of micro-voids 1110 from FIG. 11 filled with a carbon layer 1200 partially filling plurality of trenches 1100 and completely filling plurality of micro-voids 1110 in accordance with the alternate embodiment. Carbon layer 1200 partially filling plurality of trenches 1100 can be formed by sputter deposition of a carbon film on the surface of silicon carbide substrate 100 patterned with a plurality of trenches 1100 and plurality of micro-voids 1110 and blanket etching of carbon film deposited on the surface of silicon carbide substrate 100 with plurality of trenches 1100. In one embodiment, carbon layer 1200 may be formed by deposition of a polymer on the surface of silicon carbide substrate 100, etching back from a top of plurality of silicon carbide pillars 1120, and pyrolysis of the polymer layer to form carbon layer 1200 partially filling plurality of trenches 1100 and completely filling plurality of micro-voids 1110. Polymer layer used for pyrolysis to form carbon layer 1200 may be deposited by CVD (Chemical Vapor Deposition), PVD (Physical Vapor Deposition), spin coating, spray coating among other techniques.

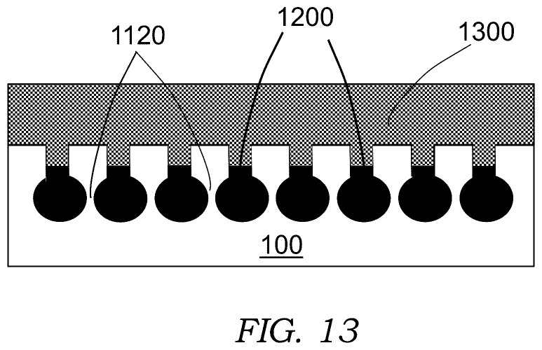

FIG. 13 is an illustration of an epitaxial layer 1300 over silicon carbide substrate 100 patterned in accordance with the alternate embodiment. In one embodiment, epitaxial layer 1300 is a silicon carbide epitaxial layer forming a buffer epitaxial layer with low defect density. Epitaxial layer 1300 is formed by placing silicon carbide substrate 100 with plurality of trenches 1100 from FIG. 11 partially filled with carbon layer 1200 over a plurality of micro-voids 1110 completely filled with carbon layer 1200 in a silicon carbide epitaxial reactor with epitaxial growth of silicon carbide using ELO (Epitaxial Lateral Overgrowth) or MELO (Merged Epitaxial Lateral Overgrowth) to form a single crystal epitaxial layer 1300 with patterned carbon layer 1200 with a plurality of silicon carbide pillars 1120.

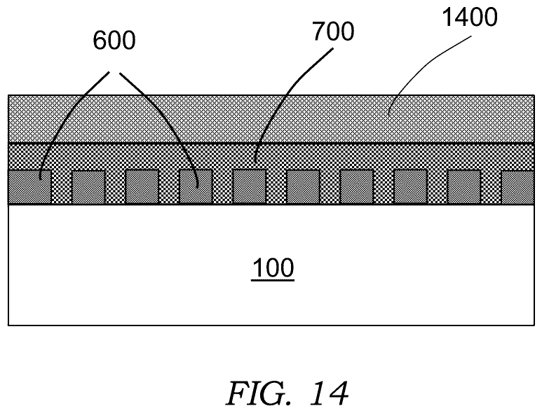

FIG. 14 is an illustration of an epitaxial layer 1400 formed overlying epitaxial layer 700 in accordance with an example embodiment. In one embodiment, a device is formed in epitaxial layer 1400 that is grown overlying epitaxial layer 700 in an epitaxial reactor. In one embodiment, epitaxial layer 1400 comprises silicon carbide. In an example embodiment, the device that is formed in epitaxial layer 1400 is a silicon carbide device that is formed in subsequent processing steps. In one embodiment, prior to the epitaxial growth of epitaxial layer 1400, a surface of epitaxial layer 700 may be lightly polished using a polishing step called kiss polish to remove any surface defects on the surface of epitaxial layer 700. In one embodiment, the doping and thickness of device epitaxial layer 1400 are determined by the electrical requirements of devices that are formed in device epitaxial layer 1400. In one embodiment, the thickness of device epitaxial layer 1400 is determined by a breakdown voltage of the device formed in the epitaxial layer 1400 in subsequent processing steps and is typically between 10-30 micrometers. In the example embodiment, epitaxial layer 1400 is doped N− and has a thickness of about 10-12 micrometers for a device breakdown voltage of 1200 Volts. Epitaxial layer 1400 formed overlying epitaxial layer 700 is used for formation of silicon carbide devices using processes well known to those skilled in the art. In the example embodiment, epitaxial layer 1400 is used for formation of a Schottky Barrier Diode in accordance with the current invention. It should be noted that epitaxial layer 1400 can be formed overlying any of the different embodiments comprising the ELO and MELO epitaxial layer disclosed herein. Also, any subsequent processing steps can also be performed in all the different embodiments disclosed herein.

In one embodiment, device epitaxial layer 1400 overlying epitaxial layer 700 enables the formation of silicon carbide devices that can subsequently be separated from silicon carbide substrate 100 by method of an exfoliation process that may be thermal, mechanical, and other techniques. A combination of techniques may also be used in the exfoliation process of device epitaxial layer 1400 and epitaxial layer 700 on which semiconductor devices can be fabricated. It should be also noted that the exfoliation process disclosed herein supports reuse of silicon carbide substrate 100 as epitaxial layer 1400 comprises only a portion of silicon carbide substrate 100. In one embodiment, a surface of silicon carbide substrate 100 can be prepared to be reused to form more devices.

In one embodiment, device epitaxial layer 1400 overlying epitaxial layer 700 may be grown to a thickness of (150-400) microns to enables the formation of silicon carbide substrate that can subsequently be separated from silicon carbide substrate 100 by method of an exfoliation process thereby enabling formation of kerfless silicon carbide substrate. In one embodiment, device epitaxial layer 1400 may be very lightly doped to act as a semi-insulating substrate.

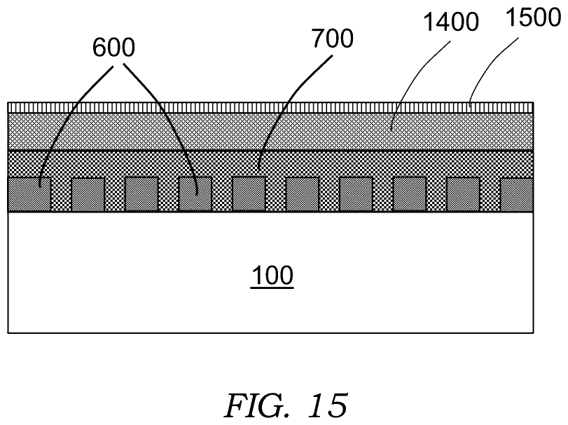

FIG. 15 is an illustration of epitaxial layer 1400 being doped to lower resistivity in accordance with an example embodiment. To reduce a contact resistance of the device, dopants are implanted on a surface of device epitaxial layer 1400. In one embodiment, a dopant species, dose, energy and other parameters are determined by the design of the Schottky Barrier Diode. In one embodiment, the implanted layer is N+. The implanted dopants are then subsequently annealed to form an ohmic contact region 1500.

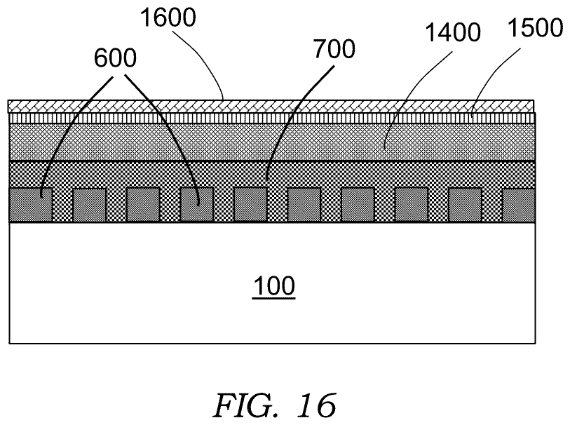

FIG. 16 is an illustration of a dielectric isolation layer 1600 deposited on ohmic contact region 1500 on epitaxial layer 1400 in accordance with an example embodiment. Dielectric isolation layer 1500 is deposited by using PECVD Silicon Dioxide, PECVD Silicon Nitride, PECVD, or Silicon Oxynitride among other films. In one embodiment, a thickness of dielectric isolation layer 1600 is in a range of (1-4) micrometers. In the example embodiment, dielectric isolation layer 1600 is PECVD Silicon Oxide and is approximately one micrometer thick.

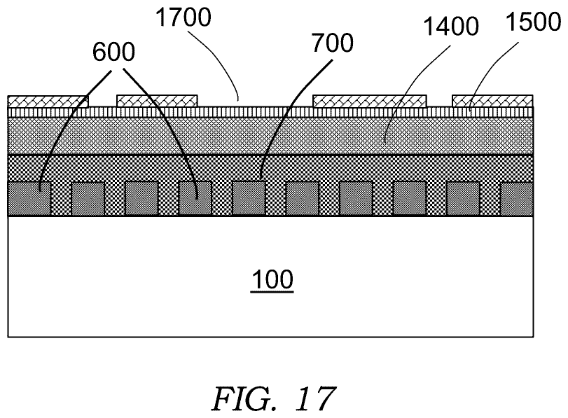

FIG. 17 is an illustration of dielectric isolation layer 1600 being patterned in accordance with an example embodiment. Dielectric isolation layer 1600 is patterned and etched using standard wafer processing steps to form contact openings 1700 exposing portion of ohmic contact region 1500 in epitaxial layer 1400. In one embodiment, patterning is done using photolithography techniques and etching of dielectric isolation layer 1600 to form contact openings 1700 is done using RIE (Reactive lon Etching), wet etching or a combination of etching steps. In the example embodiment, contact openings 1700 are patterned using RIE.

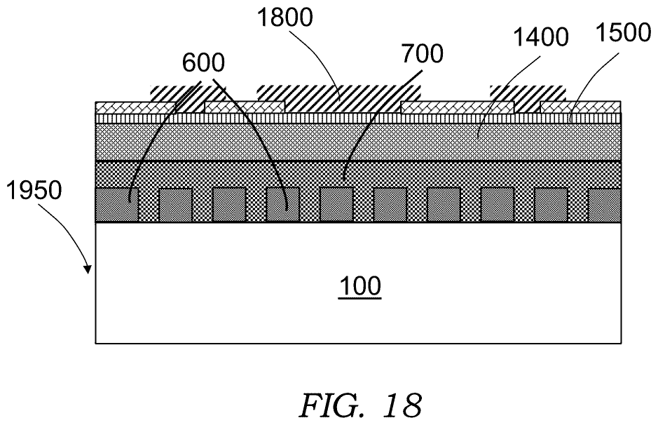

FIG. 18 is an illustration of a metal contact layer 1800 configured to form an electrode of the Schottky Diode in accordance with an example embodiment. In one embodiment, contact openings 1700 from FIG. 17 are covered with metal contact layer 1800. Metal contact layer 1800 is deposited using sputtering, e-beam evaporation, electrodeposition among other techniques and can also use a combination of metal deposition techniques. Metal contact layer 1800 may be patterned using lithography and etched. In addition, lift-off techniques may also be used for the deposition and patterning of metal contact layer 1800, as will be evident to those skilled in the art. Metal contact layer 1800 may be annealed or sintered to ensure good ohmic contact with ohmic contact region 1500 from FIG. 15. After formation of metal contact layer 1800, a passivation layer may be deposited and patterned to expose bond pads of the example device in accordance with the current invention. At this stage of the example embodiment, the fabrication of a semiconductor device such as the Schottky Barrier Diode is complete in epitaxial layer 1400 formed over epitaxial layer 700 which overlies patterned carbon layer 600, carbon layer 900 of FIG. 9, or carbon layer 1200 of FIG. 12. In an example embodiment, front side metallization results in silicon carbide substrate 100 with Schottky Barrier Diode 1950.

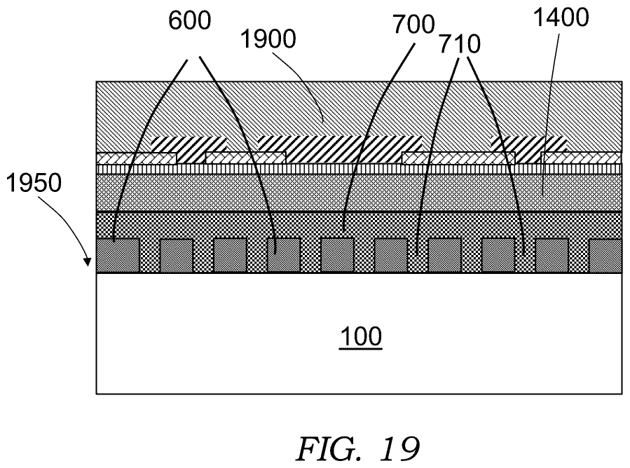

FIG. 19 is an illustration of a carrier wafer 1900 temporarily coupled to reusable silicon carbide substrate 100 with Schottky Barrier Diode 1950 in accordance with an example embodiment. In general, carrier wafer 1900 is a substrate used for handling epitaxial layer 700 and epitaxial layer 1400. Silicon carbide substrate 100 with Schottky Barrier Diode 1950 is temporarily coupled to carrier wafer 1900 to enable an exfoliation process. The exfoliation process occurs at an exfoliation layer comprising patterned carbon region 600 adjacent to plurality of silicon carbide pillars 710. Thus, patterned carbon region 600 and plurality of silicon carbide pillars 710 form a layer on a plane where separation occurs during the exfoliation process.

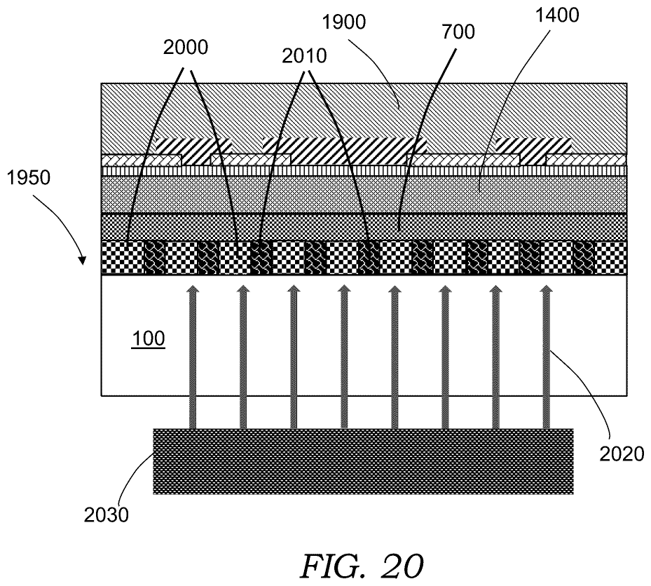

In one embodiment, a plane of the exfoliation layer is substantially parallel to the surface of substrate 100. In one embodiment, silicon carbide substrate 100 with completed Schottky Barrier Diode 1950 is attached to carrier wafer 1900 by adhesives such as UV sensitive glue among others. In the example, epitaxial layer 1400 and epitaxial layer 700 are coupled between silicon carbide substrate 100 and carrier wafer 1900. Carrier wafer 1900 may be borosilicate glass which is UV transparent and may be used with a UV curable adhesive for the bonding. Different methods of exfoliation may be used to separate semiconductor devices formed in device epitaxial layer 1400 overlying epitaxial layer 700 coupled to carrier wafer 1900 along the plane of the exfoliation layer. As an example, the exfoliation process is achieved by using an electrostatic chuck to hold the assembly of silicon carbide substrate 100 with Schottky Barrier Diode 1950 and carrier wafer 1900 and applying normal and shear stresses to fracture the exfoliation layer comprising patterned carbon region 600 and plurality of pillars 710. In another example, the exfoliation process is done using thermal stresses to initiate fracture of the exfoliation layer comprising patterned carbon region 600 and plurality of pillars 710. A combination of techniques may also be used for the exfoliation process of silicon carbide substrate 100 with device epitaxial layer 1400 and epitaxial layer 700. Note that the exfoliation process examples herein above would also work for the exfoliation layer comprising carbonized layer 900 with plurality of pillars 810 of FIG. 10 or carbonized layer 1200 of FIG. 13 filling plurality of micro-voids 1110 in FIG. 11 with plurality of pillars 1120 of FIG. 13.
FIG. 20 is an illustration of a reusable silicon carbide substrate 100 with Schottky Barrier Diode 1950 temporarily coupled to a carrier wafer 1900 undergoing an exfoliation process using a laser 2030 in accordance with an example embodiment. Reusable silicon carbide substrate 100 with Schottky Barrier Diode 1950 temporarily coupled to a carrier wafer 1900 is placed above a laser 2030 such that a laser beam 2020 is scanned into the exfoliating layer comprising patterned carbon region 600 and plurality of silicon carbide pillars 710 from FIG. 19. The wavelength of the laser 2030 is chosen so that it is substantially transparent to reusable silicon carbide substrate 100 and couples the laser energy to the patterned carbon regions 600 from FIG. 19. The laser energy is selectively absorbed by the patterned carbon layer and can reach several thousand degrees of temperature in Celsius. The laser 2030 may be used in continuous or pulsed mode. In one embodiment, laser 2030 is used in pulsed mode so that the energy coupled converts patterned carbon regions 600 to vaporized or partially vaporized carbonized regions 2000. The energy coupled to the patterned carbon regions 600 from FIG. 19 causes the plurality of silicon carbide pillars 710 in FIG. 19 to be vaporized or partially vaporized thereby forming weak regions of vaporized silicon carbide 2010. By scanning laser beam 2020 of laser 2030, the plane of patterned carbon region 600 and plurality of silicon carbide pillars 710 from FIG. 19 is converted into the exfoliating layer comprising vaporized or partially vaporized silicon carbide 2010 and vaporized or partially vaporized carbonized regions 2000. This exfoliating layer weakly couples to Schottky Barrier Diode 1950 formed in epitaxial layer 700 and epitaxial layer 1400 to reusable silicon carbide substrate 100. Laser 2030 may have a wavelength of 532 nanometers, 1064 nanometers, 623-700 nanometers or 632 nanometers for exfoliation of reusable silicon carbide substrate 100. For Gallium Nitride the appropriate wavelengths may be between 400-1000 nanometers. For silicon substrates, the appropriate wavelengths may be in the UV (Ultra-Violet) range of 350 nanometers.0. In one embodiment, the laser exfoliation process may be used prior to the device fabrication steps as described in FIG. 15-18. In this embodiment, the plane of patterned carbon region 600 and plurality of silicon carbide pillars 710 from FIG. 19 is converted into the exfoliating layer comprising vaporized or partially vaporized silicon carbide 2010 and vaporized or partially vaporized carbonized regions 2000 prior to any device formation. This exfoliating layer weakly couples the portion of substrate formed in epitaxial layer 700 and epitaxial layer 1400 to reusable silicon carbide substrate 100 prior to any device fabrication. This exfoliating layer enables the portion of substrate formed in epitaxial layer 700 and epitaxial layer 1400 to be partially released from reusable silicon carbide substrate 100 enabling easier exfoliation in a subsequent step after the device fabrication is completed. Laser 2030 may be used to optimize energy coupled to patterned carbon layer by varying the power, pulse width, pulse duration among other parameters. Laser 2030 may be operated to reduce heating of epitaxial layer 700 and epitaxial layer 1400 with a sharp fall off due to selective energy coupling to patterned carbon layer 600 from FIG. 19. By scanning laser 2030 across the entire surface of reusable silicon carbide substrate 100, the exfoliating process produces an exfoliation layer that weakly couples reusable silicon carbide substrate 100 to Schottky Barrier Diode 1950 formed in epitaxial layer 700 and epitaxial layer 1400.

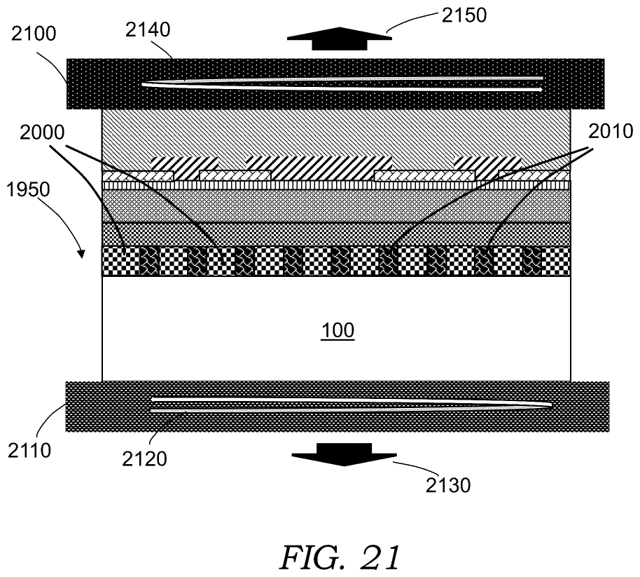

FIG. 21 is an illustration of reusable silicon carbide substrate 100 being separated from Schottky Barrier Diode 1950 in accordance with an example embodiment. As shown, Schottky Barrier Diode 1950 is temporarily coupled between carrier wafer 1900 and reusable silicon carbide substrate 100 by the exfoliation layer comprising vaporized or partially vaporized silicon carbide 2010 and vaporized or partially vaporized carbonized regions 2000.

In one embodiment, reusable silicon carbide substrate 100 with Schottky Barrier Diode 1950 is temporarily coupled to carrier wafer 1900 with exfoliation layer comprising vaporized or partially vaporized silicon carbide 2010 and vaporized or partially carbonized regions 2000 is placed in an exfoliating tool consisting of an upper portion 2100 and a lower portion 2110. A surface of the assembly of carrier wafer 1900 is coupled to upper portion 2100 of the exfoliating tool. Carrier wafer 1900 also couples to Schottky Barrier Diode 1950. The lower portion 2110 of the exfoliating tool is coupled to a surface of reusable silicon carbide substrate 100. Coupling to upper portion 2100 and lower portion 2110 of the exfoliating tool comprises an adhesive layer, UV tape, electrostatic chuck among other methods of coupling.

Exfoliating tool consisting of an upper portion 2100 and a lower portion 2110 to which the assembly of carrier 1900 and Schottky Barrier Diode 1950 and reusable silicon carbide substrate 100 is coupled is capable of exerting pulling forces normal to the surface of the assembly of carrier wafer 1900 and Schottky Barrier Diode 1950 formed overlying reusable silicon carbide substrate 100 and also rotational forces due to torque parallel to surface of carrier wafer 1900 and Schottky Barrier Diode 1950 formed overlying reusable silicon carbide substrate 100.

In one embodiment, pulling force 2150 exerted by upper portion 2100 normal to the surface of the assembly of carrier wafer 1900 and Schottky Barrier Diode 1950 formed overlying reusable silicon carbide substrate 100 may be opposite to pulling force 2130 exerted by lower portion 2110 of exfoliating tool. Rotation force imparted by upper portion 2100 produces torque 2140 parallel to surface of carrier wafer 1900 and Schottky Barrier Diode 1950 formed overlying reusable silicon carbide substrate 100 and may be of opposite direction to torque 2120 produced by lower portion 2110.

Pulling force 2150 and 2130 and torque 2140 and 2120 can be computer controlled with sensors providing a feedback mechanism to separately and simultaneously control the pulling forces and shear forces exerted on assembly of carrier wafer 1900 and Schottky Barrier Diode 1950 formed overlying reusable silicon carbide substrate 100.

Alternatively, a rotation force can be applied to one of carrier wafer 1900 or reusable silicon carbide substrate 100 instead of both. Similarly, a pulling force can be applied to one of carrier wafer 1900 or reusable silicon carbide substrate 100 instead of both.

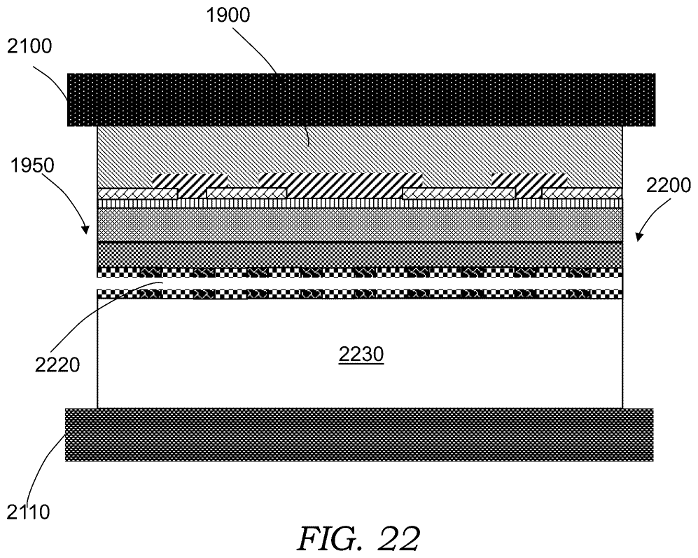

FIG. 22 is an illustration of a portion of silicon carbide substrate 2200 with Schottky Barrier Diode 1950 coupled to carrier wafer 1900 after exfoliation in an exfoliation tool in accordance with an example embodiment. Thus, a silicon carbide substrate 2200 is formed after exfoliation along a fracture plane 2220 and separated from a remaining silicon carbide substrate 2230 after the exfoliation process. In the example embodiment, silicon carbide substrate 2200 comprises epitaxial layer 700 and epitaxial layer 1400 both formed of silicon carbide. In one embodiment, assembly of completed Schottky Barrier Diode 1950 fabricated in device epitaxial layer 1400 over epitaxial layer 700 and temporarily coupled to carrier wafer 1900 is exfoliated from remaining silicon carbide substrate 2230 along the plane comprising vaporized or partially vaporized silicon carbide 2010 and vaporized or partially vaporized carbonized regions 2000 from FIG. 21. FIG. 22 is not drawn to scale since thickness of remaining silicon carbide substrate 2230 is in the range of 300-400 micrometers, while the portion of silicon carbide substrate 2200 is in the range of 20-60 micrometers.

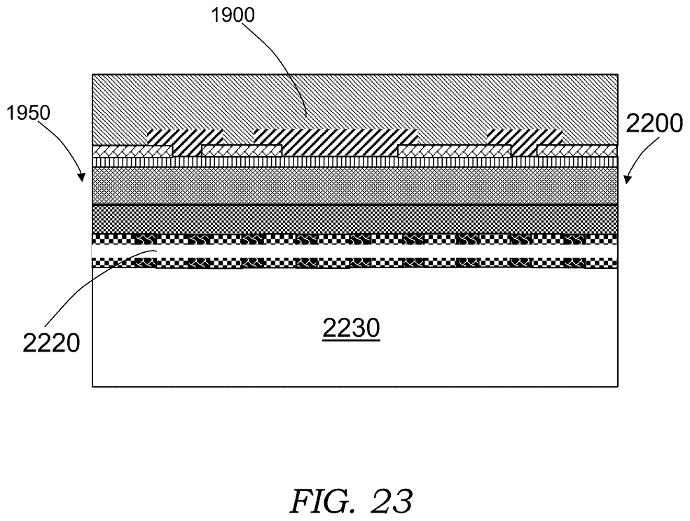

FIG. 23 is an illustration of a portion of silicon carbide substrate 2200 with Schottky Barrier Diode 1950 coupled to carrier wafer 1900 after removal from the exfoliation tool in accordance with an example embodiment. Thus, a silicon carbide substrate 2200 is formed after exfoliation along a fracture plane 2220 and separated from a remaining silicon carbide substrate 2230 after the exfoliation process. In the example embodiment, silicon carbide substrate 2200 comprises epitaxial layer 700 and epitaxial layer 1400 both formed of silicon carbide. FIG. 23 is not drawn to scale since thickness of remaining silicon carbide substrate 2230 is in the range of 300-400 micrometers, while the portion of silicon carbide substrate 2200 is in the range of 20-60 micrometers.

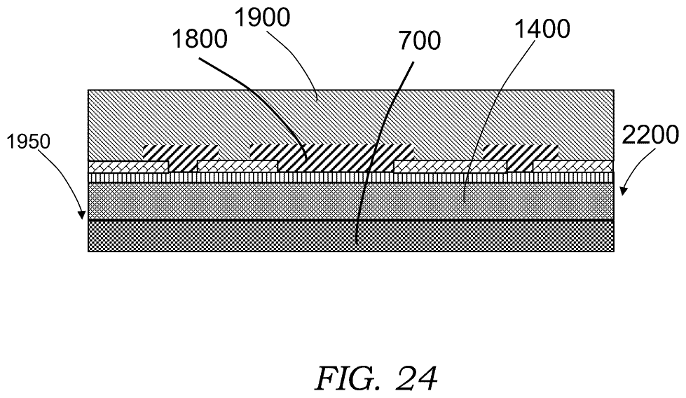

FIG. 24 is an illustration of silicon carbide substrate 2200 with Schottky Barrier Diode 1950 coupled to carrier wafer 1900 after removal by the exfoliation tool in accordance with an example embodiment. In one embodiment, silicon carbide substrate 2200 with Schottky Barrier Diode 1950 coupled to carrier wafer 1900 is processed to remove portions of vaporized or partially vaporized silicon carbide 2010 and vaporized or partially vaporized carbonized regions 2000 from FIG. 21. Portions of vaporized or partially vaporized carbonized regions 2000 from FIG. 21 may be removed by etching in an oxygen plasma exposing portions of epitaxial layer 700. In one embodiment, epitaxial layer 700 may be polished using chemical mechanical polishing after etching portions of vaporized or partially vaporized carbonized regions 2000 from FIG. 21 in an oxygen plasma.

In the example embodiment, a silicon carbide substrate of a predetermined thickness can be formed using the process disclosed herein above to improve thermal transfer and lower resistance of a silicon carbide device while lowering manufacturing cost.

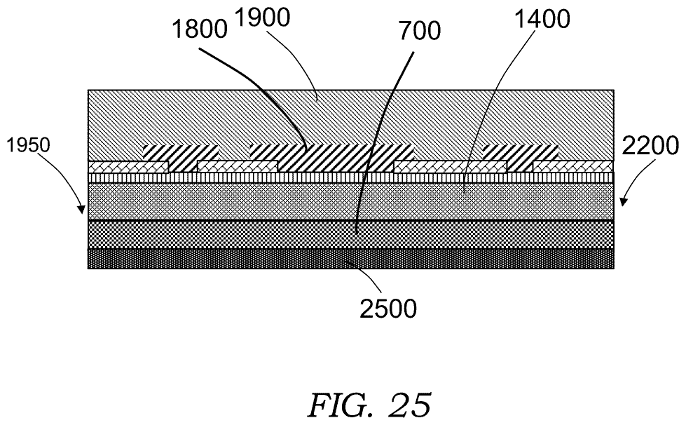

FIG. 25 is an illustration of a metal layer 2500 deposited on a surface of epitaxial layer 700 in accordance with an example embodiment. In one embodiment, silicon carbide substrate 2200 is coated with metal layer 2500 to form a backside contact of Schottky Barrier Diode 1950. In one embodiment, the surface of epitaxial layer 700 of silicon carbide substrate 2200 is polished and metal layer 2500 is deposited on the surface of epitaxial layer 700 with good ohmic contact using evaporation, sputtering and other methods of metal deposition. Epitaxial layer 700 is formed with N+doping to ensure good ohmic contact with metal layer 2500. Metals such as nickel, or combination of metals such as Ti/Ni/Au (Titanium/Nickel/Gold) may be used along with annealing to reduce contact resistance to surface of epitaxial layer 700. In one embodiment, laser annealing may be used to reduce contact resistance of metal layer 2500.

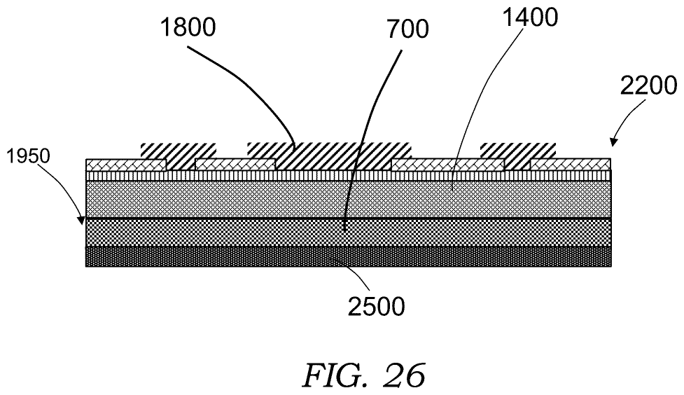

FIG. 26 is an illustration of silicon carbide substrate 2200 with Schottky Barrier Diode 1950 separated from carrier wafer 1900 of FIG. 25 in accordance with an example embodiment. In one embodiment, after metal layer 2500 is deposited, the entire assembly comprising of silicon carbide substrate 2200 and carrier wafer 1900 is attached to a blue dicing tape. Carrier wafer 1900 is then separated from silicon carbide substrate 2200 which is coupled to the dicing tape. In the example embodiment, silicon carbide substrate 2200 with completed Schottky Barrier Diode 1950 is then diced and assembled in packages

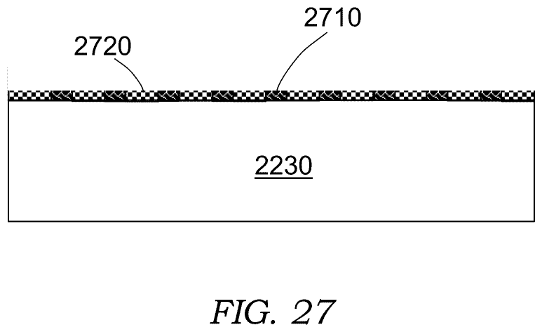

FIG. 27 is an illustration of a remaining silicon carbide substrate 2230 separated from silicon carbide substrate 2200 from FIG. 26 after the exfoliation process in accordance with an example embodiment. Remaining silicon carbide substrate 2230 is separated from silicon carbide substrate 2200 with portions of vaporized or partially vaporized carbon region 2720 and vaporized or partially vaporized silicon carbide region 2710 on the surface of remaining silicon carbide substrate 2230. Remaining silicon carbide substrate 2230 is a majority portion of silicon carbide substrate 100 from FIG. 1 after the exfoliation process and is further processed to make remaining silicon carbide substrate 2230 suitable for reuse.

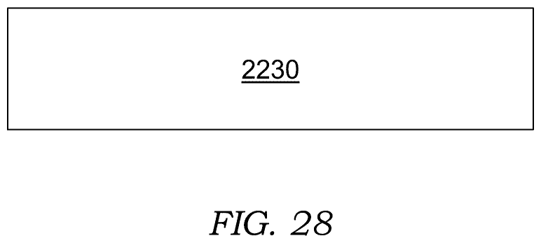

FIG. 28 is an illustration of further processing of the remaining silicon carbide substrate 2230 separated from silicon carbide substrate 2200 from FIG. 26 after the exfoliation process in accordance with an example embodiment. Remaining silicon carbide substrate 2230 separated from silicon carbide substrate 2200 is polished with portions of vaporized or partially vaporized carbon region 2720 and vaporized or partially vaporized silicon carbide region 2710 removed from the surface of remaining silicon carbide substrate 2230 is further processed to make it suitable for reuse.

As previously disclosed herein above, silicon carbide substrate 2230 is a majority portion of silicon carbide substrate 100 from FIG. 20 and is reclaimed by re-polishing a surface exposed to fracture plane 2220 from FIG. 23 such that a polished surface is suitable for formation of semiconductor devices using the current invention.

The polishing of the surface of silicon carbide substrate 2230 to form reclaimed silicon carbide substrate 2230 is performed using CMP (chemical mechanical polishing), electrochemical polishing among other methods. Reclaimed silicon carbide substrate 2230 can be used for successive formation of semiconductor devices using the same silicon carbide substrate 100 but with a portion removed by each subsequent exfoliation process.

By successive application of the current invention of formation of patterned carbon region 600 and plurality of silicon carbide pillars 710 from FIG. 7, epitaxial growth of epitaxial layer 700, epitaxial growth of drift region in epitaxial layer 1400, device formation in epitaxial layer 1400, exfoliation by using a laser beam to vaporize carbon region 600 and plurality of silicon carbide pillars 710 and re-polishing of the severed substrate, the reusable silicon carbide substrate 100 may be re-used multiple times. By the successive application of the current invention as described by the example embodiment, the same reusable silicon carbide substrate 100 can be used for fabrication of silicon carbide semiconductor devices leading to significant reduction in the cost of fabrication of silicon carbide semiconductor devices. By application of the exfoliation process using patterned carbon layer and laser exfoliation, silicon carbide devices can be fabricated with lower RDS (drain to source resistance) leading to higher electrical efficiency and lower thermal resistance.

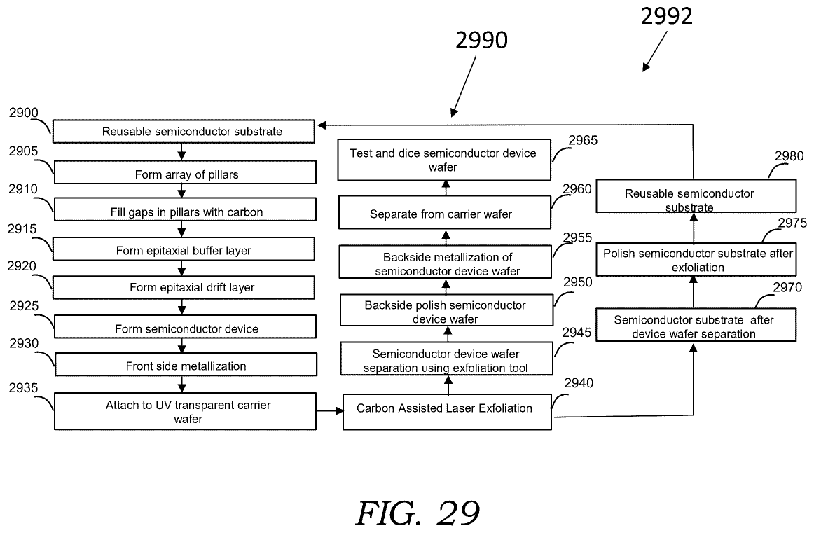

FIG. 29 is an illustration of a block diagram 2992 of an exfoliation process 2990 in accordance with an example embodiment. Substrate forming process and exfoliation process 2990 supports reuse of semiconductor substrate in the manufacture of semiconductor devices. The order of the blocks in block diagram in FIG. 29 is for illustrative purposes only and does not imply an order or show all the specific steps in the implementation of the invention as are known by one skilled in the art.

In one embodiment, blocks 2900, 2905, 2910, 2915, 2920, 2925, 2930, 2935, 2940, 2945, 2950, 2955, 2960 and 2965 comprises the formation of a substrate and exfoliation process 2990 to separate the substrate from the reusable semiconductor substrate. In the example, the substrate comprises at least a first semiconductor epitaxial layer and a second semiconductor epitaxial layer and semiconductor devices are formed in the substrate. In one embodiment, no semiconductor devices are formed in the semiconductor substrate but the semiconductor substrate is used to form the substrate comprising at least two epitaxial semiconductor layers. In the block diagram 2992, block 2900 illustrates the semiconductor substrate used in an example embodiment. In block 2905, an array of pillars is formed in semiconductor substrate and gaps in pillars are filled with carbon as shown in block 2910. After filling gaps in array of pillars with carbon, buffer epitaxial layer is formed as shown in block 2915 followed by forming of epitaxial drift layer, as shown in block 2920. Buffer epitaxial layer and epitaxial drift layer comprise a semiconductor substrate. Block 2925 illustrates the step of forming at least one semiconductor device. Block 2930 shows the front side metallization of the at least one semiconductor device. Block 2935 shows the step of attaching the completed semiconductor device wafer with front side metallization to a UV transparent carrier wafer. The assembly of completed semiconductor device layer and carrier wafer is then subjected to the exfoliation process 2990.

Block 2940 shows the exfoliation of substrate with at least one semiconductor device after exfoliation process 2990 using a laser to couple to patterned carbon layer in gaps of pillars formed in semiconductor substrate such that the semiconductor substrate is separated from the substrate comprising at least two semiconductor epitaxial layers.

Block 2945 shows semiconductor substrate comprising at least two semiconductor epitaxial layers with at least two semiconductor devices separated using an exfoliation tool. Block 2950 shows the step of polishing backside of the substrate followed by block 2955 showing the step of backside metallization of the substrate. Block 2960 shows the step of separating the substrate with completed semiconductor devices from the carrier wafer followed by block 2965 showing the step of testing and dicing of the substrate. In the example, a plurality of semiconductor devices is formed on or in the substrate and these are diced to separate the semiconductor devices for packaging. Block 2970 shows the portion of remaining semiconductor substrate after exfoliation of semiconductor device wafer as shown in block 2940. Block 2975 of polishing remaining semiconductor substrate after exfoliation for reuse for multiple semiconductor devices and reuse as reusable semiconductor substrate for formation of semiconductor devices as shown in block 2980. As mentioned herein above, only a fraction of the semiconductor substrate is used in the formation of the substrate. A remaining portion of the semiconductor substrate can be reused to form more substrates and more devices thus, extending the life of the semiconductor substrate and forming the devices on the substrate or a controlled and predetermined thickness.

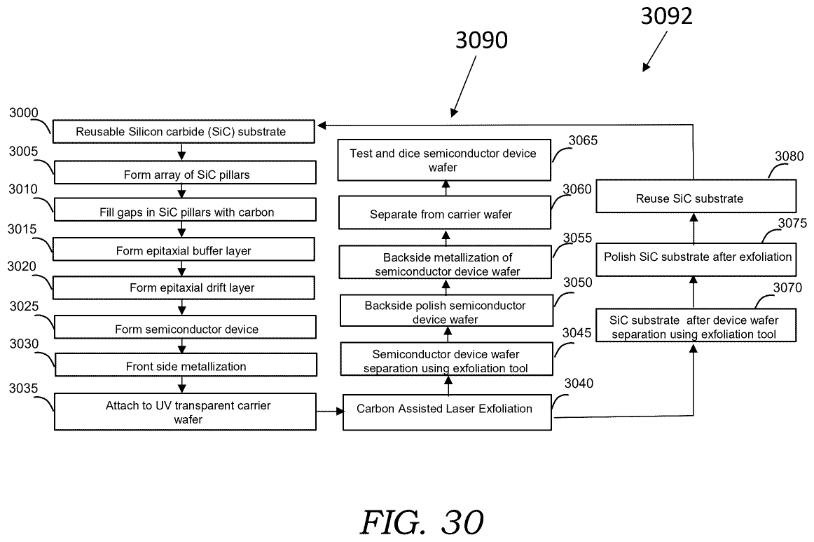

FIG. 30 is an illustration of a block diagram 3092 of an exfoliation process 3090 in accordance with an example embodiment. Substrate forming process and exfoliation process 3090 supports reuse of semiconductor substrate in the manufacture of semiconductor devices. The order of the blocks in block diagram in FIG. 30 is for illustrative purposes only and does not imply an order or show all the specific steps in the implementation of the invention as are known by one skilled in the art.

In one embodiment, blocks 3000, 3005, 3010, 3015, 3020, 3025, 3030, 3035, 3040, 3045, 3050,3055, 3060 and 3065 comprises the formation of a substrate and exfoliation process 3090 to separate the substrate from the reusable semiconductor substrate. In the example, the substrate comprises at least a first semiconductor epitaxial layer and a second semiconductor epitaxial layer and semiconductor devices are formed in the substrate. In one embodiment, no semiconductor devices are formed in the semiconductor substrate but the semiconductor substrate is used to form the substrate comprising at least two epitaxial semiconductor layers. In the block diagram 3092, block 3000 illustrates the reusable silicon carbide substrate 100 used in an example embodiment. In block 3005, an array of pillars 710 is formed in silicon carbide substrate and gaps in pillars are filled with carbon as shown in block 3010. After filling gaps in array of pillars with carbon, buffer epitaxial layer 700 of silicon carbide is formed as shown in block 3015 followed by forming of epitaxial drift layer 1400 of silicon carbide, as shown in block 3020. Buffer epitaxial layer and epitaxial drift layer comprise a semiconductor substrate. Block 3025 illustrates the step of forming at least one semiconductor device. Block 3030 shows the front side metallization 1800 of the at least one semiconductor device. Block 3035 shows the step of attaching the completed semiconductor device wafer in silicon carbide substrate with front side metallization to a UV transparent carrier wafer 1900. The assembly of completed semiconductor device layer in silicon carbide substrate and carrier wafer is then subjected to the exfoliation process 3090.

Block 3040 shows the exfoliation of silicon carbide substrate with at least one semiconductor device after exfoliation process 3090 using a laser 2030 to couple to patterned carbon layer in gaps of pillars formed in silicon carbide substrate such that the silicon carbide substrate is separated from the substrate comprising at least two semiconductor epitaxial layers.

Block 3045 shows silicon carbide substrate comprising at least two silicon carbide epitaxial layers with at least two semiconductor devices separated using an exfoliation tool. Block 3050 shows the step of polishing backside of the substrate followed by block 3055 showing the step of backside metallization 2500 of the substrate. Block 3060 shows the step of separating the substrate with completed semiconductor devices from the carrier wafer followed by block 3065 showing the step of testing and dicing of the substrate. In the example, a plurality of semiconductor devices is formed on or in the substrate and these are diced to separate the semiconductor devices for packaging. Block 3070 shows the portion of remaining silicon carbide substrate 2230 after exfoliation of semiconductor device wafer as shown in block 3040. Block 3075 shows the step of polishing remaining silicon carbide substrate after exfoliation for reuse for multiple semiconductor devices and reuse as reusable silicon carbide substrate for formation of semiconductor devices as shown in block 3080. As mentioned herein above, only a fraction of the silicon carbide substrate is used in the formation of the substrate. A remaining portion of the silicon carbide substrate can be reused to form more substrates and more devices thus, extending the life of the silicon carbide substrate and forming the devices on the substrate or a controlled and predetermined thickness.

In one embodiment, a method of forming a silicon carbide (SIC) wafer using epitaxial growth is described. The silicon carbide wafer is also called a silicon carbide substrate since it is the basic material or starting material on which different semiconductor devices are formed using semiconductor designs and processes. The silicon carbide wafer or substrate can be used for different semiconductor devices such as BJTs, MOSFETs, TrenchFETS, SBDs, RF devices, optical devices such as lasers, diodes, detectors among other devices.

The process of producing SiC wafers starts with the growth of SiC bulk crystals (called boules) grown from a seed crystal using the sublimation growth method, typically along the 0001 direction. Since the growth rate of the bulk crystal of SiC is quite slow and prone to defects, the usable length of the SiC boules is limited and typically are only between 30-50 mm. The silicon carbide boule produced by PVT (Physical Vapor Transport) is done at a high temperature of about 2300C and takes about a week to produce a boule. The process of producing SiC wafers from the SiC boules consist of slicing wafers that are sliced off-axis from the cylindrical boules. In one embodiment, the resulting off-axis 4H-SiC wafer is usually tilted 4 degrees towards the [1120] or [0001] direction to produce wafers with silicon carbide epitaxy with low defect density.

A method of forming a silicon carbide wafer (SiC) is described. In an example embodiment, the method comprises using a silicon carbide wafer that is used multiple times to form a reusable silicon carbide substrate or wafer. It is to be understood that silicon carbide wafer and silicon carbide substrate are used interchangeably by those skilled in the art. Silicon carbide wafers produced as described above are used as starting substrates for the fabrication of various semiconductor devices using designs and processes suitable for the fabrication of these semiconductor devices. Since silicon carbide wafers are used as the platform on which these semiconductor devices are fabricated, it is also customary to call these silicon carbide wafers also as silicon carbide substrates. Because the cost of the silicon carbide substrates comprise a significant portion for the fabrication of the semiconductor devices, it will be advantageous to be able to reuse the silicon carbide substrate multiple times.

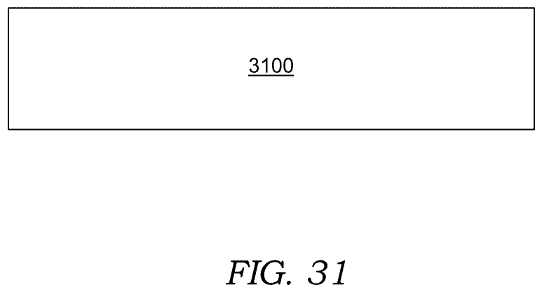

FIG. 31 is an illustration of a silicon carbide (SIC) substrate 3100 in accordance with an example embodiment. Silicon carbide substrate 3100 may be also be called a silicon carbide wafer and can be produced either from a boule of silicon carbide grown by PVT or may be produced by epitaxial growth of silicon carbide using a silicon carbide epitaxial reactor. The thickness of SiC substrate 3100 may be in the range of 300-1000 micrometers and may be doped p-type or n-type, depending on the semiconductor devices formed in SiC substrate 3100. In the example embodiment, silicon carbide (SIC) substrate 3100 is used multiple times for the fabrication of semiconductor devices and thus may also be called a reusable silicon carbide substrate. 000125 The process of producing SiC wafers starts with the growth of SiC bulk crystals (called boules) grown from a seed crystal using the sublimation growth method, typically along the 0001 direction. Since the growth rate of the bulk crystal of SiC is quite slow and prone to defects, the usable length of the SiC boules are only between 30-50 mm. The process of producing SiC wafers from the SiC boules consist of slicing wafers that are sliced off-axis from the cylindrical boules. In one embodiment, the resulting off-axis 4H-SiC wafer is usually tilted 4 degrees towards the [1120] or [0001] direction to produce wafers with silicon carbide epitaxy with low defect density.

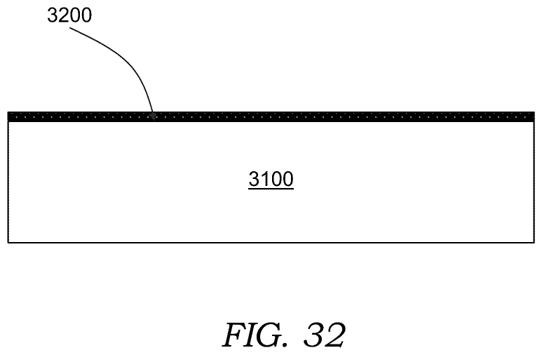

FIG. 32 is an illustration of a hard mask layer 3200 that is deposited overlying silicon carbide substrate 3100, in accordance with an example embodiment. Hard mask layer 3200 is deposited overlying a surface of silicon carbide substrate 3100 by using techniques such as CVD (Chemical Vapor Deposition), LPCVD (low pressure chemical vapor deposition), PECVD (Plasma Enhanced Chemical Vapor Deposition), APCVD (Atmospheric Pressure Chemical Vapor Deposition), SACVD (Sub Atmospheric Chemical Vapor Deposition) among other techniques. PVD (Physical Vapor Deposition), or ALD (Atomic layer Deposition) may also be used for hard mask layer 3200. In the example implementation, hard mask layer 3200 comprises PECVD (Plasma Enhanced Chemical Vapor Deposition) silicon oxide. The thickness of silicon oxide hard mask layer 3200 is selected based on the requirements of subsequent processing steps as described in the example implementation and is in the range of 100-4000 nm. The thickness of hard mask layer 3200 is determined by the specific requirements of the implementation and is well known to one skilled in the art. In another embodiment, a second hard mask layer may be deposited over hard mask layer 3200. In one embodiment, hard mask layer 3200 comprises PECVD silicon dioxide and the second hard mask layer comprises PECVD amorphous silicon. In another embodiment, hard mask layer 3200 comprises a metal layer such as nickel. In other embodiments, multiple hard mask layers may be used.

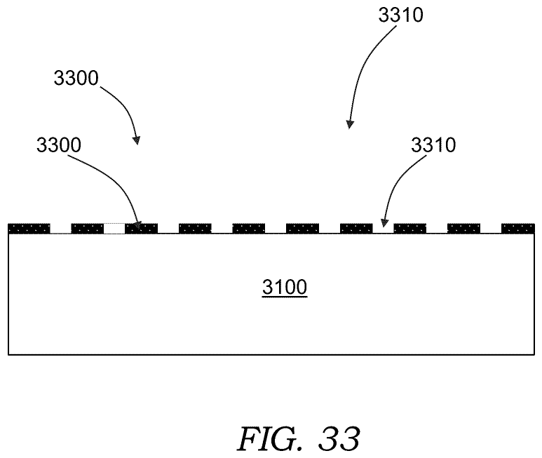

FIG. 33 is an illustration of the patterned hard mask 3300 in accordance with an example embodiment. Hard mask 3200 from FIG. 32 is patterned to form patterned hard mask 3300 with a plurality of openings 3310. Hard mask layer 3200 from FIG. 32 is patterned using optical lithography such as a stepper, contact aligner, projection aligner among other tools. An optically sensitive layer called photoresist is used to transfer the pattern generated by CAD (Computer Aided Design) using industry standard software programs. The optical lithography process may use UV, DUV, EUV to transfer the pattern to the hard mask layer. The shape of the patterns may be squares, triangles, hexagons, diamonds or other shapes. The size of the patterns and openings are determined by the specific requirements of the epitaxial process that is used in subsequent fabrication steps. The size of the patterns and plurality of openings may be in the range of 500 nm to 5 micrometers (um). The optical lithography process is used to transfer the patterns to plurality of openings 3310.

In another embodiment, plurality of openings 3310 are implemented using an electron beam direct write technique. In yet another embodiment, plurality of openings 3310 are implemented using Nano-Imprint Lithography (NIL). In another embodiment, plurality of openings 3310 are implemented using Direct Laser Write.

The choice of the photoresist layer, thickness of the photoresist layer, the exposure and develop times for the subsequent chemical steps are well known to those skilled in the art and determined by the requirements of accurate pattern transfer from the photoresist layer to hard mask layer 3200 of FIG. 32 to subsequently form plurality of openings 3310 and leave patterned hard mask 3300. In one embodiment, plurality of openings 3310 cover an entire surface or substantially all of the surface of silicon carbide substrate 3100. After the pattern transfer is completed using lithography, the next step is the patterning of hard mask layer 3200 of FIG. 32 using etching techniques to selectively remove hard mask layer 3200 of FIG. 32 thereby leaving patterned hard mask 3300 overlying silicon carbide substrate 3100. The selective removal of hard mask layer 3200 of FIG. 32 to form patterned hard mask 3300 may use Reactive lon Etching (RIE). Different gases may be used to form a plasma to selectively remove the portions of hard mask layer 3200 of FIG. 32 exposed by the patterned photoresist. The choice of gases for the RIE is determined by hard mask layer 3200 of FIG. 32 used in the implementation. In the example embodiment, with a silicon oxide used as hard mask layer 3200 of FIG. 32, fluorine-based chemistries such as SF₆, CF₄, CHF₃, and other gases may be used in the RIE. Accordingly, in the example embodiment with silicon oxide as hard mask layer 3200 of FIG. 32, plurality of openings 3310 are etched in hard mask layer 3200 of FIG. 32 using a fluorine-based chemistry. Patterned hard mask 3300 remains in areas overlying silicon carbide substrate 3100 to protect or mask the surface of silicon carbide substrate 3100 from etching. After patterning hard mask layer 3200, the photoresist is stripped using techniques well known to those skilled in the art and may be dry, wet or a combination of dry and wet processing.

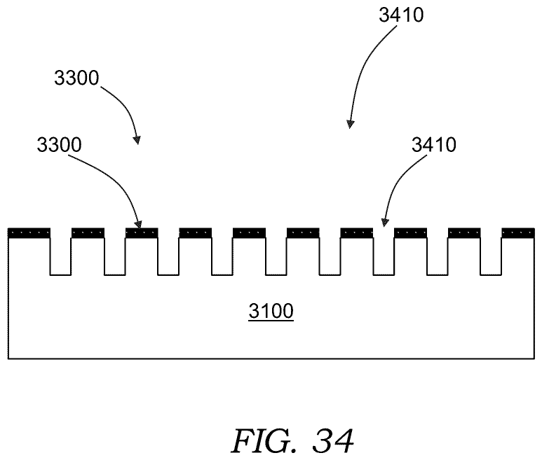

FIG. 34 is an illustration of a pattern 3410 etched in silicon carbide substrate 3100, in accordance with an example embodiment. In the example embodiment, pattern 3410 is formed by the etching of silicon carbide substrate 3100. In one embodiment, the surface of silicon carbide substrate 3100 exposed by the patterning of the hard mask layer is etched using a RIE (Reactive lon Etching Process). Pattern 3410 formed in silicon carbide substrate 3100 may be in the form of trenches or pillars with an aspect ratio that is determined by the requirements of epitaxial growth in subsequent processing of the example embodiment. In one embodiment, an inductively coupled plasma (ICP) with high density may be used to form pattern 3410.

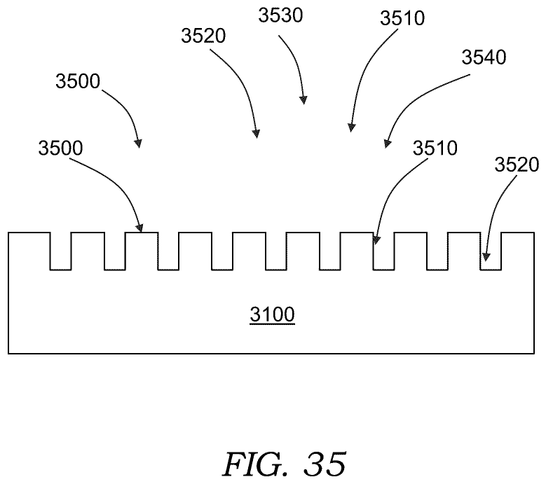

FIG. 35 is an illustration of a patterned layer 3500 that is formed in accordance with an example embodiment. Patterned layer 3500 is formed by the removal of patterned hard mask 3300 of FIG. 33. In an example embodiment, patterned layer 3500 is formed by removal of patterned hard mask 3300 of FIG. 33 by using wet or dry chemical etching and is determined by the choice of hard mask material. In the example embodiment, patterned hard mask 3300 of FIG. 33 comprises a PECVD silicon oxide layer that is removed by a wet chemical etch of BHF (Buffered Hydrofluoric Acid). Other solutions for etching PECVD silicon oxide may include HF (Hydrofluoric Acid) in various dilutions in water.

Patterned layer 3500 may comprise a plurality of pillars 3530 and can be shaped as triangles or hexagons to expose (1120) or equivalent crystal planes since these orientations facilitate high quality epitaxial overgrowth with low defect density in subsequent processing steps in accordance with the current invention. Plurality of pillars 3530 are formed by a plurality of trenches 3540 etched in silicon substrate 3100 as disclosed in FIG. 34. In one embodiment, patterned layer 3500 comprises plurality of pillars 3530 that has a height 3510 in the range of (500-5000) nanometers (nm) and spacings 3520 between adjacent pillars in the range of (500-5000) nm and is determined by the requirements of silicon carbide epitaxy that is subsequently described herein. In one embodiment, the profile of plurality of pillars 3530 comprising patterned layer 3500 may be substantially vertical. In another embodiment, the profile of plurality of pillars 3530 comprising patterned layer 3500 may be tapered so that it is wider at the base of the pillar and narrower towards the surface of plurality of pillars 3530. In another embodiment, the profile of plurality of pillars 3530 comprising patterned layer 3500 may be tapered from the base of each pillars to come to a point at the surface of each pillar of the plurality of pillars 3530.

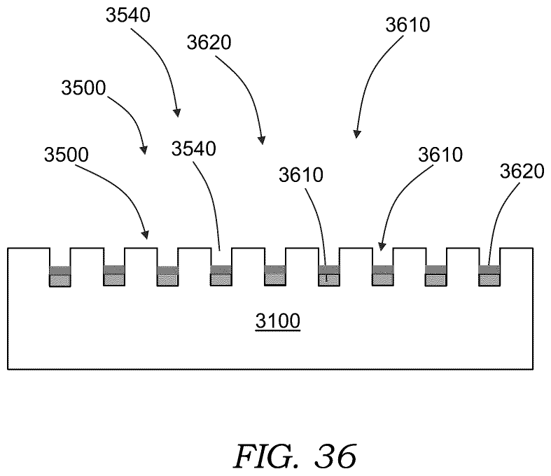

FIG. 36 is an illustration of a layer of heatable material 3610 and a protective layer 3620 in accordance with an example embodiment. Layer of heatable material 3610 and protective layer 3620 are formed in patterned layer 3500 to enable an exfoliation process that is subsequently described herein. In one example embodiment, layer of heatable material 3610 and protective layer 3620 are formed in plurality of trenches 3540 between plurality of pillars 3530 formed in patterned layer 3500. In one example embodiment, the height of layer of heatable material 3610 and protective layer 3620 are together less than height 3510 of each pillar of plurality of pillars 3530.

The layer of heatable material 3610 and protective layer 3620 may be formed using different processes using semiconductor process technology as well known to those skilled in the art. The layer of heatable material 3610 may comprise different materials that are selectively heated by a laser or array of lasers. The layer of heatable material 3610 may comprise carbon, tantalum carbide among other materials. The layer of heatable material may comprise different materials that can be formed using different processes. In an example embodiment, the layer of heatable material 3610 comprises carbon. In an example embodiment, layer of heatable material 3610 comprising carbon is physical vapor deposition (PVD) of a carbon layer. The PVD carbon is deposited on the entire surface of patterned layer 3500 and is then etched using an oxygen plasma such that the PVD carbon remains in plurality of trenches 3640 to form layer of heatable material 3610. In another embodiment, the layer of heatable material 3610 is formed by the spin coating of a polymer such as photoresist over the surface of patterned layer 3500. The spin coated photoresist layer is then pyrolyzed and converted to carbon. The spin coated photoresist layer is pyrolyzed and converted to carbon using a vacuum furnace at a high temperature of (900-1400)° C. in an inert environment of nitrogen where it undergoes volumetric shrinkage. Any thickness of the layer of heatable material 3610 above the surface of patterned layer 3500 is reduced by etching in a plasma of oxygen, argon or other gases that is used to etch heatable material 3610 comprising carbon. Other methods of carbon deposition may include CVD (chemical vapor deposition), ALD (Atomic layer Deposition) among other methods.

Protective layer 3620 formed over layer of heatable material 3610 may be formed by using different materials and different deposition processes. Protective layer 3620 is used to protect the layer of heatable material 3610 during an epitaxial growth process in subsequent process steps of growing silicon carbide epitaxial layers. It is necessary to protect the layer of heatable material 3610 from being removed by the reactive hydrogen at high temperatures since the epitaxial growth process is carried out in an epitaxial reactor at high temperatures (1500-1900)° C. and uses hydrogen annealing of the surface of patterned layer 3500 of silicon carbide substrate 3100 to prepare the surface for silicon carbide epitaxial growth. Protective layer 3620 protects the layer of heatable material 3610 during the hydrogen annealing step in the silicon carbide epitaxial growth. Protective layer 3620 may be deposited by PVD, sputter deposition among other methods and may comprise tantalum carbide. In one embodiment, protective layer 3620 is deposited and then subsequently etched such that the thickness of protective layer 3620 and heatable material 3610 is below height 3510 of patterned layer 3500. In one embodiment, protective layer 3620 comprising tantalum carbide and heatable material 3610 comprising carbon are below the surface of patterned layer 3500. In one embodiment, the heatable material 3610 and protective layer 3620 may both comprise tantalum carbide only.

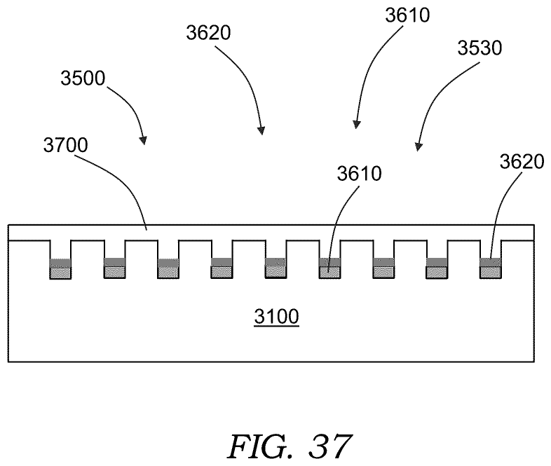

FIG. 37 is an illustration of an epitaxial layer 3700 grown overlying patterned layer 3500 in accordance with an example embodiment. In the example embodiment, epitaxial layer 3700 is grown by on-axis epitaxial lateral overgrowth over patterned layer 3500. In one example, epitaxial layer 3700 is grown over patterned layer 3500 comprising plurality of pillars 3530 such that the lateral epitaxial overgrowth forms a continuous layer overlying plurality of pillars 3530. In the example embodiment, epitaxial layer 3700 is a merged epitaxial lateral overgrowth (MELO) layer since the epitaxial layer growing laterally from the top and sidewall of plurality of pillars of patterned layer 3500 merge to form one continuous layer overlying surface of silicon carbide substrate 3100. Epitaxial layer 3700 formed by MELO is a crystalline layer and is grown to have the same crystalline orientation of underlying patterned layer 3500 formed overlying silicon carbide substrate 3100.

Epitaxial layer 3700 comprising a MELO layer has a very low defectivity propagating from the surface of patterned layer 3500. In one embodiment, epitaxial layer 3700 comprising a MELO layer has a defectivity lower than underlying silicon carbide substrate 3100. In one embodiment, epitaxial layer 3700 has very low defectivity due to the lateral epitaxial overgrowth from the top surface and sidewalls of the plurality of pillars of patterned layer 3500 ultimately merging to form one contiguous layer. In the formation of epitaxial layer 3700 comprising a MELO layer, the epitaxial growth between the pillars are inhibited by heatable material 3610 and protective layer 3620 such that the lateral epitaxial overgrowth is enabled from the top surface and sidewalls of the plurality of pillars resulting in the merging of epitaxial fronts from adjacent pillars to form a continuous epitaxial layer. This results in the formation of a continuous epitaxial layer that is virtually free of epitaxial defects such as basal plane dislocations, stacking faults, threading dislocations, edge dislocations among other defects. Epitaxial layer 3700 comprising a MELO layer is therefore an epitaxial layer with very low defect density resulting in a high quality epitaxial layer suitable for the fabrication of high reliability semiconductor devices. Epitaxial layer 3700 thus forms a contiguous surface overlying the surface of silicon carbide substrate 3100 to support the formation of low defectivity epitaxial layers of different thicknesses thereafter.

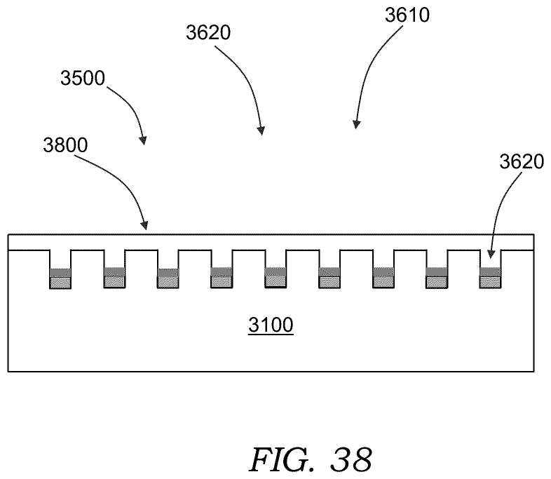

FIG. 38 is an illustration of a surface 3800 of epitaxial layer 3700 in accordance with an example embodiment. Epitaxial layer 3700 from FIG. 37 is planarized with CMP (Chemical Mechanical Planarization) to improve the surface planarity and make it suitable for the formation of low defectivity epitaxial layers of different thicknesses thereafter. In the example embodiment, surface 3800 is the planarized surface of epitaxial layer 3700 after the CMP.

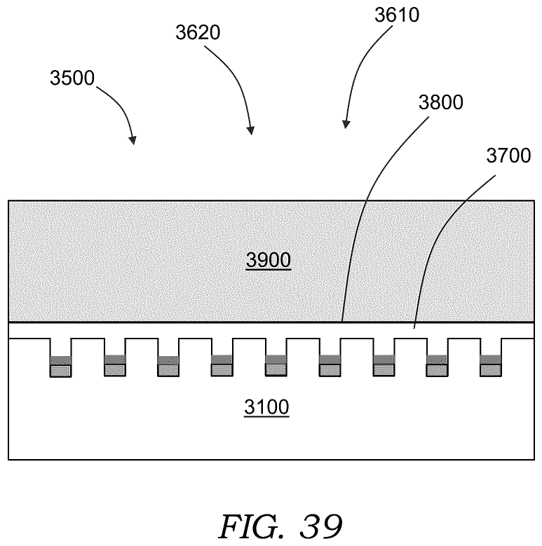

FIG. 39 is an illustration of an epitaxial layer 3900 grown overlying epitaxial layer 3700 in accordance with an example embodiment. In the example embodiment, epitaxial layer 3900 is grown overlying epitaxial layer 3700 by vertical epitaxial growth in an epitaxial reactor. Epitaxial layer 3900 is grown by using vertical epitaxial growth to a thickness suitable for use as a substrate to form semiconductor devices. Epitaxial layer 3900 is a single crystal layer and has the same crystalline orientation of the underlying MELO layer (epitaxial layer 3700) overlying silicon carbide substrate 3100. The thickness of epitaxial layer 3900 is grown such that it is comparable in thickness to a silicon carbide substrate that is cut from a boule using standard process for forming silicon carbide wafers or substrates. The thickness of epitaxial layer 3900 is in the range of 300-900 micrometers and may comprise one epitaxial layer or multiple epitaxial layer. The doping of epitaxial layer may be n-type or p-type depending on the type of semiconductor devices formed in subsequent fabrication steps. In one embodiment, epitaxial layer 3900 is grown in a multi-wafer epitaxial reactor that has high epitaxial growth rates. The thickness of epitaxial layer is chosen such it is able to withstand all the mechanical, thermal, chemical stresses due to typical fabrication process steps used in the fabrication of SiC semiconductor devices such as deposition, lithography, etch, metallization, implant, anneal among other process steps, as will be evident to those skilled in the art.

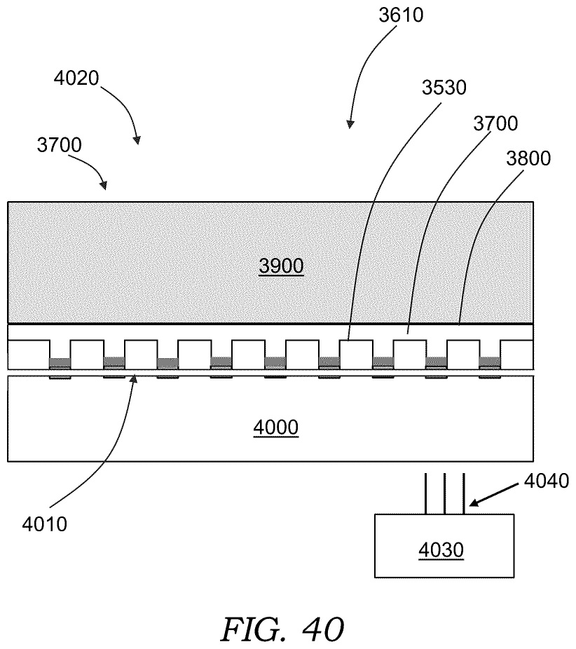

FIG. 40 is an illustration of an epitaxial silicon carbide substrate 4020 formed in accordance with an example embodiment. In an example embodiment, SiC substrate 3100 of FIG. 39 is exposed to one or more lasers 4030 that are substantially transparent to silicon carbide. In one embodiment, energy 4040 from the one or more lasers 4030 are focused through the backside of silicon carbide substrate 3100 of FIG. 39 and couples selectively with heatable material 3610 of FIG. 39 formed in patterned layer 3500. The energy 4040 from the one or more lasers 4030 is transparent to SiC substrate 3100 of FIG. 39 and does not heat up silicon carbide substrate 3100 or epitaxial layers 3700 or 3900. Thus, one or more lasers 4030 selectively couples with heatable material 3610 of FIG. 39 in patterned layer 3500 causing a thermal shock to the patterned layer. In the example embodiment, patterned layer comprising plurality of pillars 3530 is subjected to a thermal shock that fractures or weakens plurality of pillars 3530 resulting in a fracture plane 4010. In one embodiment, heating carbon as heatable material 3610 of FIG. 39 reaches temperatures that can vaporize silicon carbide material of plurality of pillars 3530. In one embodiment, one or more lasers 4030 can be continuous lasers or pulsed lasers. In one embodiment, one or more lasers 4030 are scanned such that the carbon as heatable material 3610 of FIG. 39 is heated for a predetermined time. In one embodiment, local heat radiated by carbon as heatable material 3610 is heated for the predetermined time dissipates rapidly and the heat does not traverse a great distance in either substrate 3100 of FIG. 39 or epitaxial layers 3700 and 3900. In general, the thermal shock that causes the fracture is a result of rapid heating and rapid cooling of patterned layer 3500 by proximity of heatable material 3610 of FIG. 39. The fracture plane from the selective heating of heatable material 3610 of FIG. 39 causes an exfoliation of an epitaxial silicon carbide substrate 4020 from the original silicon carbide substrate 3100 with a remnant major portion forming a new silicon carbide substrate 4000. In the example embodiment, silicon carbide substrate 4020 comprises epitaxial layer 3900, epitaxial layer 3700, and a portion of patterned layer 3500. New silicon carbide substrate 4000 after exfoliation of silicon carbide 4020 has a reduced thickness and includes a portion of patterned layer 3500. It is to be noted that epitaxial silicon carbide substrate 4020 and silicon carbide substrate 4000 are not drawn to scale. In one embodiment, a mechanical force or torque may be applied to separate epitaxial silicon carbide substrate 4020 and silicon carbide substrate 4000 during the exfoliation process.

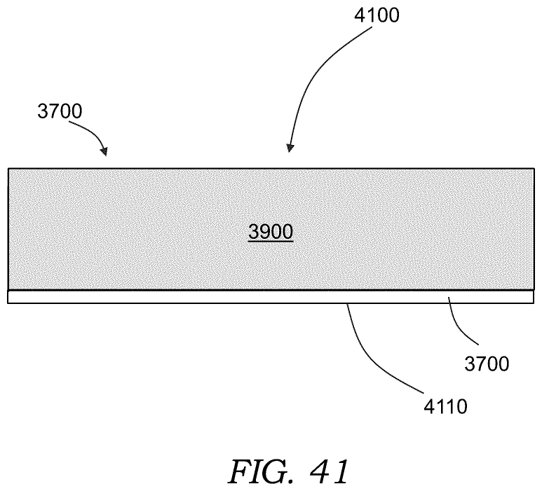

FIG. 41 is an illustration of a reusable silicon carbide substrate 4100 in accordance with an example embodiment. In the example embodiment, epitaxial silicon carbide substrate 4020 of FIG. 40 is further processed after the exfoliation process to form reusable silicon carbide substrate 4100. In one embodiment, epitaxial silicon carbide substrate 4020 of FIG. 40 is polished using CMP to remove remnants of patterned layer 3500 of FIG. 40 to form polished surface 4110 of epitaxial layer 3700 formed by merged epitaxial layer lateral overgrowth. Reusable silicon carbide substrate 4100 comprises epitaxial layer 3700 formed by merged epitaxial lateral overgrowth and one or more epitaxial layer 3900 formed by vertical epitaxial growth. It is to be noted that reusable silicon carbide substrate 4100 is formed by epitaxial growth as compared to silicon carbide substrate 3100 that may be formed from a silicon carbide boule or by epitaxial growth and exfoliation. Since reusable silicon carbide substrate 4100 is grown using silicon carbide epitaxy, it can be substantially less in cost and higher in quality with reduced defect density providing potentially large advantages in cost and reliability. In another embodiment, epitaxial layer 3700 may be completely polished and removed such that only epitaxial layer 3900 remains.

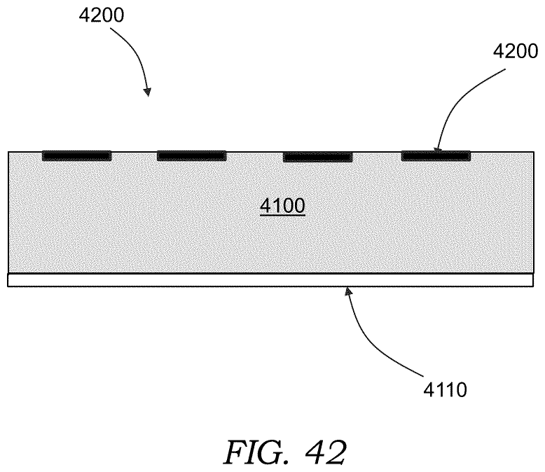

FIG. 42 is an illustration of semiconductor devices 4200 formed in reusable silicon carbide substrate 4100 in accordance with an example embodiment. In one embodiment, reusable silicon carbide substrate 4100 is used to form semiconductor devices 4200 in the surface opposite to polished surface 4110. In another embodiment, reusable silicon carbide substrate 4100 is used to form semiconductor devices 4200 in the surface of polished surface 4110. In the example embodiment, semiconductor devices 4200 are formed in reusable silicon carbide substrate 4100 in the surface opposite to polished surface 4110. Semiconductor devices 4200 may comprise MOSFET, Bipolar junction transistors, IGBTs among other devices and may be fabricated by using one or more epitaxial layers formed overlying reusable silicon carbide substrate 4100 using device designs and fabrication processes that are well known to those skilled in the art.

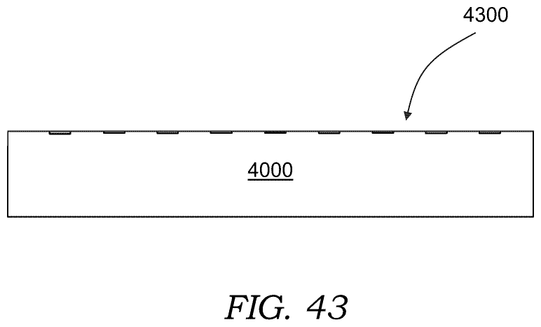

FIG. 43 is an illustration of silicon carbide substrate 4000 of FIG. 40 in accordance with an example embodiment. Silicon carbide substrate 4000 of FIG. 40 is formed by the major portion of silicon carbide substrate 3100 of FIG. 31 after the exfoliation process. In FIG. 43, the separation of silicon carbide substrate 3100 to form silicon carbide substrate 4000 due to the exfoliation process using one or more lasers results in an exfoliated surface 4300 that has residual portions of patterned layer 3500 of FIG. 40.

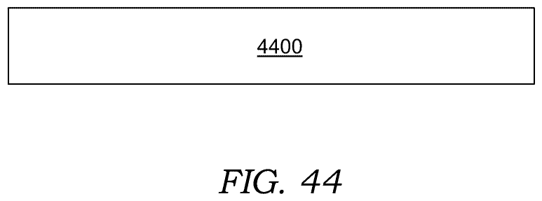

FIG. 44 is an illustration of a reclaimed silicon carbide substrate 4400 in accordance with an example embodiment. In the example embodiment, silicon carbide substrate 4000 of FIG. 40 is polished using CMP to remove a portion of exfoliated surface 4300 of FIG. 43 to form reclaimed silicon carbide substrate 4400. Since reclaimed silicon carbide substrate 4400 is formed from silicon carbide substrate 3100, it can be reclaimed multiple times to produce multiple reusable silicon carbide substrates 4100 of FIG. 41 using the process steps described in FIGS. (31-43).

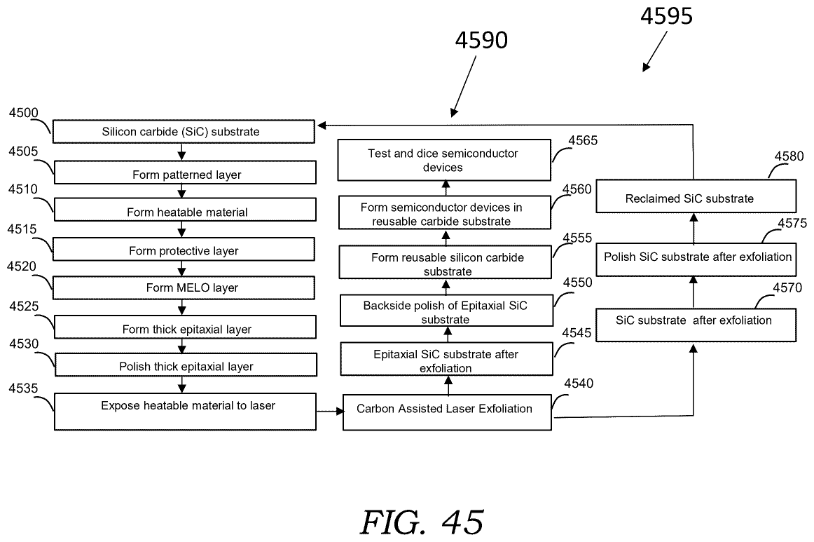

FIG. 45 shows the block diagram 4595 for the formation of a reusable silicon carbide wafer in accordance with an example embodiment.

The order of the blocks in FIG. 45 is for illustrative purposes only and does not imply an order or show all the specific steps in the implementation of the invention as are known by one skilled in the art.

In block diagram 4595, block 4500 shows a silicon carbide substrate used as the starting material for the formation of a reusable silicon carbide wafer, in accordance with an example embodiment. There are no size limitations on silicon carbide substrate size and the process contemplates semiconductor wafer or substrate sizes greater than 300 millimeters. Block 4505 shows the formation of a patterned layer overlying the silicon carbide substrate. In block 4510, a heatable material is formed in the patterned layer, followed by the formation of a protective layer overlying the heatable material, as shown in block 4515. Block 4520 shows the formation of epitaxial layer using MELO (merged epitaxial lateral overgrowth) to form a contiguous layer overlying the patterned layer. The epitaxial layer of block 4520 is formed by lateral epitaxial overgrowth on a surface and sidewalls of the patterned layer. Block 4525 shows the formation of a thick epitaxial layer overlying the MELO with a thickness suitable for formation of a silicon carbide substrate. The thick epitaxial layer can comprise one or more epitaxial layers. The polishing of the surface of the thick epitaxial layer is shown in block 4530. The exposure of the heatable material in the patterned layer is shown in block 4335 which results in a carbon assisted laser exfoliation as shown in block 4540. In one embodiment, the heatable material is carbon. In one embodiment, the heatable material is heated by one or more lasers. In one embodiment, the one or more lasers are scanned to heat the heatable material for a predetermined time. The formation of an epitaxial silicon carbide substrate after exfoliation is shown in block 4545. The backside of the epitaxial silicon carbide substrate formed by the exfoliation is polished as shown in block 4550 which results in a reusable silicon carbide substrate as shown in block 4555. As mentioned previously, there are no size limitations on the epitaxial silicon carbide substrate size and the process contemplates that the epitaxial silicon carbide substrate can be greater than 300 millimeters. The formation of semiconductor devices in the reusable silicon carbide substrate is shown in block 4560. Since many semiconductor devices are formed in the reusable silicon carbide substrate, they are tested and then diced and assembled in packages as shown in block 4565.

Block diagram 4590 shows the formation of a reclaimed silicon carbide substrate that is used multiple times for the formation of silicon carbide substrates used for fabrication of semiconductor devices. Block 4570 shows the silicon carbide substrate after the exfoliation process that comprises the major portion of the silicon carbide substrate in block 4500. The silicon carbide substrate from block 4570 is polished after the exfoliation as shown in block 4575. The reclaimed silicon carbide substrate that is formed after the polishing process is shown in block 4580. As mentioned previously, the reclaimed SiC substrate does not have a size limitation and can be 300 millimeters or greater. The reclaimed silicon carbide substrate can now be used multiple times for the formation of epitaxial silicon substrates providing significant advantages in cost, performance, quality, and reliability in the semiconductor devices that are formed using this invention.

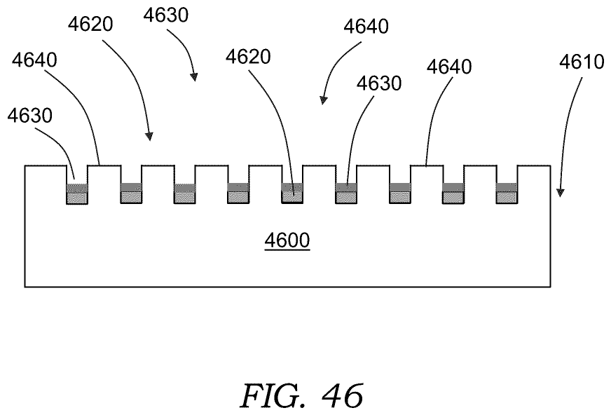

FIG. 46 is an illustration of a silicon carbide substrate 4600 with a patterned layer 4610 in accordance with another example embodiment. In the example embodiment, silicon carbide substrate 4600 may be formed from a boule or may be epitaxially grown. Silicon carbide substrate 4600 may be doped n-type or p-type depending on the semiconductor devices that are subsequently formed. Silicon carbide substrate 4600 comprises patterned layer 4610 that is formed on a surface of silicon carbide substrate 4600 using lithography and etch as disclosed hereinabove. Patterned layer 4610 may be in different shapes such as squares, hexagons, triangles among other shapes. Patterned layer 4610 may comprise a plurality of pillars 4640 that may have a predetermined aspect ratio between the height, width and spacing between adjacent pillars. Patterned layer 4610 further comprises a heatable material 4620 and a protective layer 4630. In general, a plurality of trenches are etched into silicon carbide substrate 4600 to form plurality of pillars 4640. Heatable material 4620 is a layer formed in a bottom of the plurality of trenches. Protective layer 4630 is formed overlying the heatable material within the plurality of trenches. Protective layer 4630 is below a surface of each pillar of the plurality of pillars 4640 to support merged epitaxial lateral overgrowth. Heatable material 4620 formed in patterned layer 4610 can be selectively heated by one or more lasers of a specific wavelength such that only the heatable material is heated. Heatable material 4620 may comprise of materials such as carbon, tantalum carbide among other materials that can be selectively heated by a laser. In one embodiment, heatable material 4620 comprises carbon and be formed by physical vapor deposition or by pyrolysis of polymer material such as photoresist, polyimide, parylene among other materials. Protective layer 4630 is formed overlying heatable material 4620 in patterned layer 4610 to protect heatable material 4620 during subsequent high temperature processes using in epitaxial silicon carbide growth. In one embodiment, protective layer 4630 comprises tantalum carbide. The combined thickness of heatable material 4620 and protective layer 4630 is less than the height of patterned layer 4610 formed in silicon carbide substrate 4600.

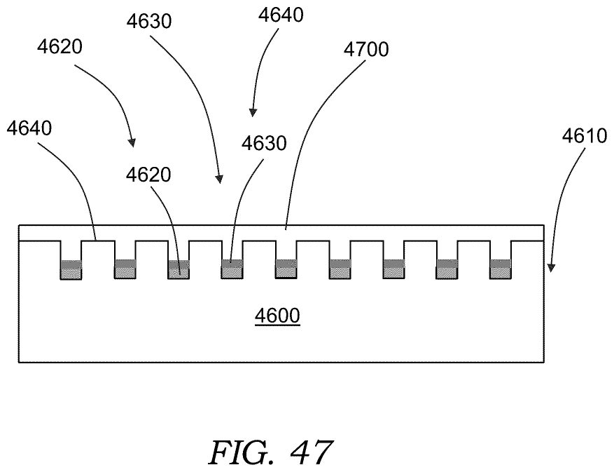

FIG. 47 is an illustration of a silicon carbide epitaxial layer 4700 grown overlying patterned layer 4610 in accordance with an example embodiment. Silicon carbide epitaxial layer 4700 forms a first silicon carbide epitaxial layer and is grown overlying patterned layer 4610 by using merged epitaxial lateral growth (MELO) such that the silicon carbide epitaxial fronts from the sidewalls and top surface of patterned layer 4610 grows laterally and merges to form a contiguous surface overlying patterned layer 4610. Since silicon carbide epitaxial layer 4700 is formed by MELO, it reduces the defect density of typical epitaxial defects by orders of magnitude leading to the formation of epitaxial layer 4700 that has high quality and suitable to the formation of semiconductor devices that have higher performance and reliability. Silicon carbide epitaxial layer 4700 is a crystalline layer that has the same crystal orientation of the underlying patterned layer 4610. The doping and thickness of silicon carbide epitaxial layer 4700 is chosen to make it suitable for the formation of semiconductor devices. In one embodiment, silicon carbide epitaxial layer forms a C-face (carbon face layer) that is suitable for formation of semiconductor of devices with higher mobility.

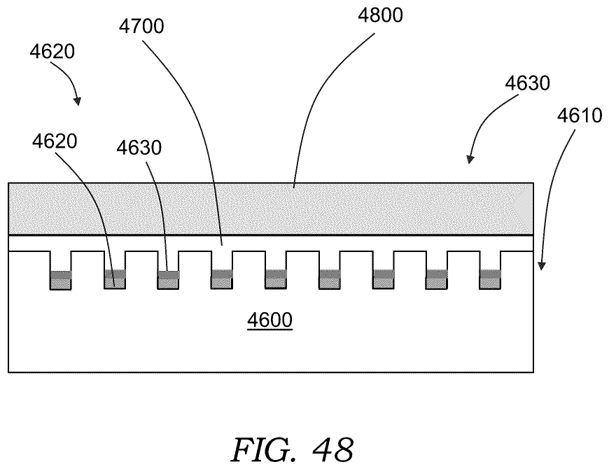

FIG. 48 is an illustration of silicon carbide epitaxial layer 4800 grown overlying silicon carbide epitaxial layer 4700 in accordance with an example embodiment. Silicon carbide epitaxial layer 4800 is a second silicon carbide epitaxial layer and is grown above MELO layer comprising silicon carbide epitaxial layer 4700 with the same crystalline orientation. Silicon carbide epitaxial layer 4800 is formed by epitaxial vertical overgrowth overlying silicon carbide epitaxial layer 4700 formed by merged epitaxial lateral overgrowth. The doping and thickness of silicon carbide epitaxial layer 4800 is suitable for its use as a drift layer for a semiconductor device.

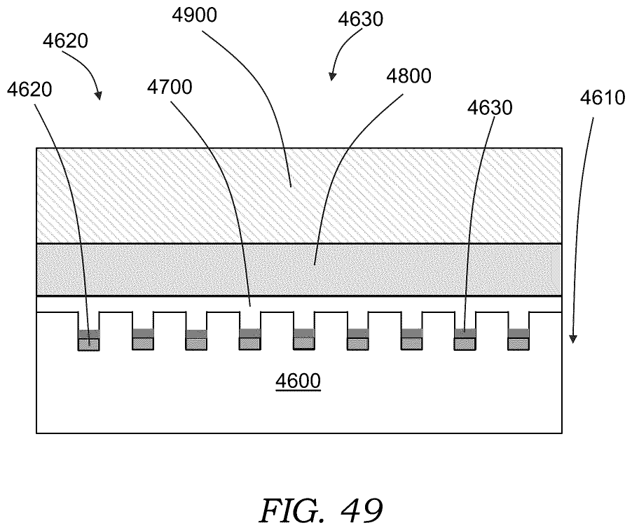

FIG. 49 is an illustration of a silicon carbide epitaxial layer 4900 formed overlying silicon carbide epitaxial layer 4800 in accordance with an example embodiment. Silicon carbide epitaxial layer 4900 is formed overlying silicon carbide epitaxial layer 4800 to form a silicon carbide substrate that is suitable for semiconductor device fabrication. The thickness of silicon carbide epitaxial layer 4900 is in the range of (300-900) microns and is chosen such that the thickness makes it suitable to be used as a starting substrate for fabrication of semiconductor devices. The thickness of silicon carbide epitaxial layer 4900 is such that it is mechanically strong to withstand the stresses (mechanical, thermal, chemical) imparted during the fabrication steps of semiconductor devices. In one embodiment, silicon carbide epitaxial layer 4900 is a single crystal layer and is formed by epitaxial vertical overgrowth overlying silicon carbide epitaxial layer 4800. In another embodiment, silicon carbide epitaxial layer 4900 is a polycrystalline layer and is formed by epitaxial vertical overgrowth overlying silicon carbide epitaxial layer 4800. In another embodiment, silicon carbide epitaxial layer 4900 may be formed by bonding a polycrystalline silicon carbide wafer to surface of silicon carbide epitaxial layer 4800. In one embodiment, silicon carbide epitaxial layer 4900 may be heavily doped to reduce the series resistance of the semiconductor devices. In another embodiment, silicon carbide epitaxial layer 4900 may be very lightly doped or undoped to produce a substrate with a semi-insulating layer suitable for the fabrication of semiconductor devices that require very high electrical insulation.

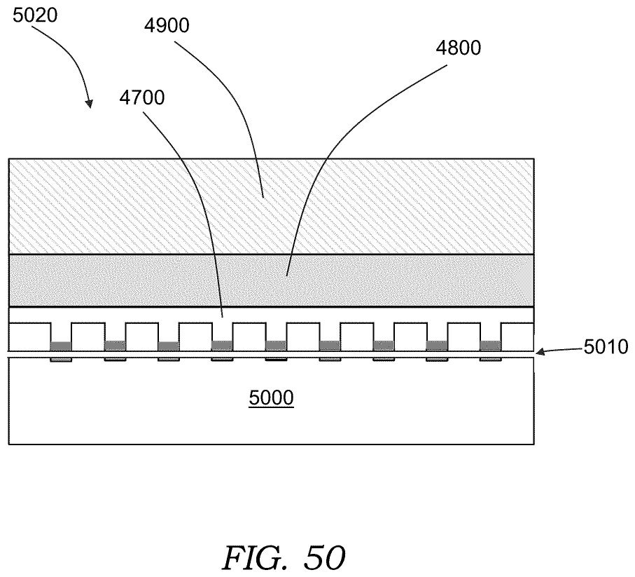

FIG. 50 is an illustration of a silicon carbide substrate 5000 formed by exfoliation in accordance with an example embodiment. In the example embodiment, a laser or multiple lasers are used to couple energy to heatable material 4620 of FIG. 49 such that it is selectively heated as compared to silicon carbide substrate 4600 and patterned layer 4610 of FIG. 49. The selective heating of heatable material 4610 causes an exfoliation of silicon carbide substrate 4600 in the plane of patterned layer 4610 forming a fracture plane 5010 that is substantially parallel to the surface of patterned layer 4610. Fracture plane 5010 is formed due to thermal shock and mechanical stress that results in the formation of silicon carbide substrate 5000 and epitaxial silicon carbide substrate 5020. Silicon carbide substrate 5000 is formed by exfoliation and comprises a major portion of the original silicon carbide substrate 4600 of FIG. 49 and is shown not drawn to scale. Epitaxial silicon carbide substrate 5020 is formed by exfoliation and comprises silicon carbide epitaxial layer 4700 formed by merged epitaxial lateral overgrowth, silicon carbide epitaxial layer 4800 formed by vertical epitaxial overgrowth, and silicon carbide epitaxial layer 4900 formed by vertical epitaxial overgrowth.

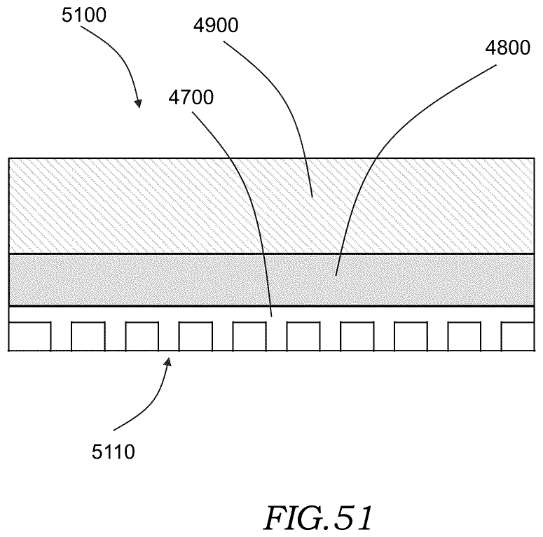

FIG. 51 is an illustration of a reusable epitaxial silicon carbide substrate 5100 in accordance with an example embodiment. Reusable epitaxial silicon carbide substrate 5100 is formed by the exfoliation process and comprises silicon carbide epitaxial layer 4700 formed by merged epitaxial lateral overgrowth, silicon carbide epitaxial layer 4800 formed by vertical epitaxial overgrowth, and silicon carbide epitaxial layer 4900 formed by vertical epitaxial overgrowth. The thickness of reusable epitaxial silicon carbide substrate 5100 is suitable to provide sufficient mechanical strength for the formation of semiconductor devices in subsequent process steps. Reusable epitaxial silicon carbide substrate 5100 is polished using CMP to remove portions of protective layer 4620 of FIG. 49 and any remnants of heatable material 4610 of FIG. 49 resulting in a polished surface 5110 comprising a portion of patterned layer 4610 of FIG. 49.

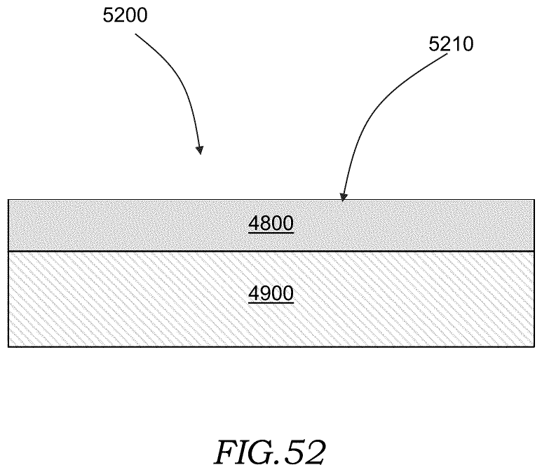

FIG. 52 is an illustration of a reusable epitaxial silicon carbide substrate 5200 in accordance with an example embodiment. In the example embodiment, reusable epitaxial silicon carbide substrate 5200 is formed by polishing and removing a portion of patterned layer 4610 of FIG. 49 and silicon carbide epitaxial layer 4700 of FIG. 51 thereby exposing epitaxial layer silicon carbide epitaxial layer 4800. Reuseable epitaxial silicon carbide substrate 5200 comprises silicon carbide epitaxial layer 4800 and silicon carbide epitaxial layer 4900 with a polished surface 5210.

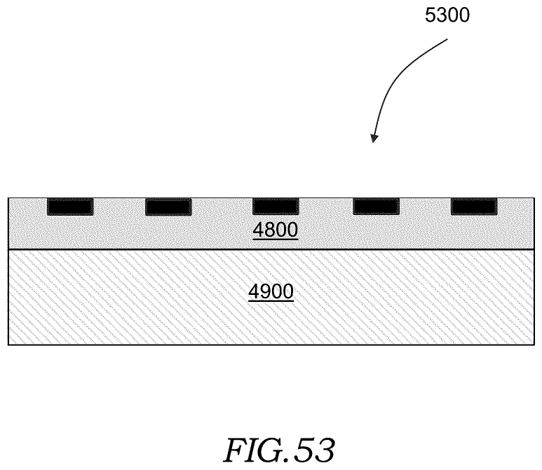

FIG. 53 is an illustration of a plurality of semiconductor devices 5300 formed in reusable epitaxial silicon carbide substrate 5200 in accordance with an example embodiment. Plurality of semiconductor devices 5300 are formed in reusable epitaxial silicon carbide substrate 5200 using designs and processes that are used in semiconductor fabrication, as will be evident to those skilled in the art. Since silicon carbide epitaxial layer 4800 is grown with low defectivity, it can be used to produce semiconductors of high quality and performance. If silicon carbide epitaxial layer 4800 is grown with C-face (Carbon face), it can be used to produce semiconductors with higher mobility.

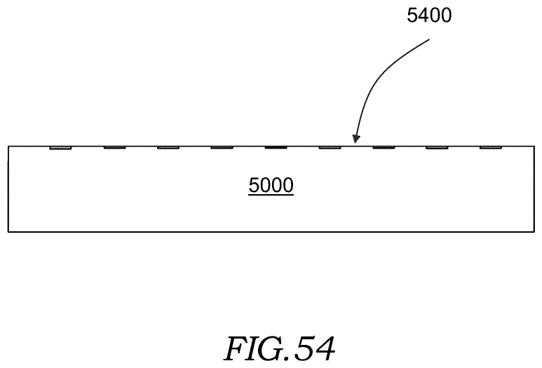

FIG. 54 is an illustration of silicon carbide substrate 5000 in accordance with an example embodiment. Silicon carbide substrate 5000 comprises silicon carbide substrate 4600 of FIG. 49 and a remaining portion of patterned layer 4610 of FIG. 49 after the exfoliation process. In FIG. 50, the separation of silicon carbide substrate 4600 to form silicon carbide substrate 5000 due to the exfoliation process using one or more lasers results in an exfoliated surface 5400 that has residual or remaining portions of patterned layer 4610 of FIG. 49.

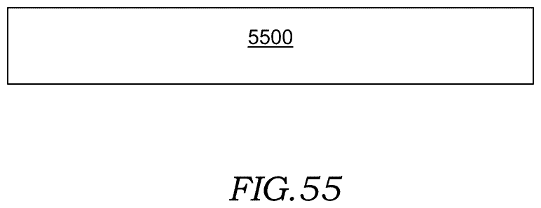

FIG. 55 is an illustration of a reclaimed silicon carbide substrate 5500 in accordance with an example embodiment. In the example embodiment, silicon carbide substrate 5000 is polished using CMP to remove a portion of exfoliated surface 5400 to form reclaimed silicon carbide substrate 5500 to expose silicon carbide substrate 5000. Since reclaimed silicon carbide substrate 5500 is formed from silicon carbide substrate 4600 of FIG. 49, it can be reclaimed or reused multiple times to produce reusable epitaxial silicon carbide substrate 5200 using the process steps described in FIGS. (46-55).

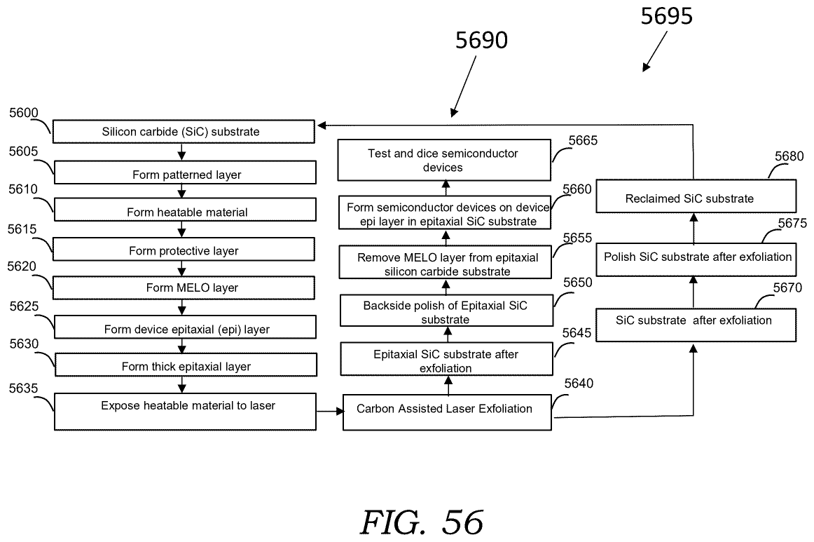

FIG. 56 shows the block diagram 5695 for the formation of a reusable silicon carbide wafer in accordance with an example embodiment.

The order of the blocks in FIG. 56 is for illustrative purposes only and does not imply an order or show all the specific steps in the implementation of the invention as are known by one skilled in the art.

In block diagram 5695, block 5600 shows a silicon carbide substrate used as the starting material for the formation of a reusable silicon carbide wafer, in accordance with an example embodiment. There are no size limitations on silicon carbide substrate size and the process contemplates semiconductor wafer or substrate sizes greater than 300 millimeters. Block 5605 shows the formation of a patterned layer overlying the silicon carbide substrate. In one embodiment, patterned layer shown in block 5605 may comprise a plurality of pillars of SiC. In block 5610, a heatable material is formed in the patterned layer, followed by the formation of a protective layer overlying the heatable material, as shown in block 5615. Block 5620 shows the formation of an epitaxial layer using MELO to form a contiguous layer overlying the patterned layer. Block 5625 shows the formation of a device epitaxial (epi) layer overlying the MELO layer shown in block 5620. Block 5630 shows the formation of a thick epitaxial layer overlying the device epitaxial layer in block 5625 with a thickness suitable for formation of a silicon carbide substrate. Thick epitaxial layer shown in block 5630 may be single crystal or polycrystalline. The exposure of the heatable material in the patterned layer is shown in block 5635 which results in a carbon assisted laser exfoliation as shown in block 5640. The formation of an epitaxial silicon carbide substrate after exfoliation is shown in block 5645. There are no size limitations on the epitaxial silicon carbide substrate size and the process contemplates the epitaxial silicon carbide semiconductor wafer or substrate having sizes greater than 300 millimeters. The backside of the epitaxial silicon carbide substrate formed by the exfoliation is polished as shown in block 5650 which is further polished to remove the MELO layer, as shown in block 5655. The formation of semiconductor devices in the device epi layer in the epitaxial silicon carbide substrate is shown in block 5660. Since many semiconductor devices are formed in the reusable silicon carbide substrate, they are tested and then diced and assembled in packages as shown in block 5665.

Block diagram 5690 shows the formation of a reclaimed silicon carbide substrate that is used multiple times for the formation of silicon carbide substrates used for fabrication of semiconductor devices. Block 5670 shows the silicon carbide substrate after the exfoliation process that comprises the major portion of the silicon carbide substrate in block 5600. As mentioned previously, are no size limitations on the silicon carbide substrate size and the process contemplates the semiconductor wafer or substrate sizes greater than 300 millimeters. The silicon carbide substrate from block 5670 is polished after the exfoliation as shown in block 5675. The reclaimed silicon carbide substrate that is formed after the polishing process is shown in block 5680. The reclaimed silicon carbide substrate can now be used multiple times for the formation of epitaxial silicon substrates providing significant advantages in cost, performance, quality, and reliability in the semiconductor devices that are formed using this invention.

While the present invention has been described with reference to certain preferred embodiments or methods, it is to be understood that the present invention is not limited to such specific embodiments or methods. Rather, it is the inventor's contention that the invention be understood and construed in its broadest meaning as reflected by the following claims. Thus, these claims are to be understood as incorporating not only the preferred methods described herein but all those other and further alterations and modifications as would be apparent to those of ordinary skilled in the art.

The descriptions disclosed herein below will call out components, materials, inputs, or outputs from FIGS. 1-56.

In one embodiment, an exfoliation process comprises using a reusable silicon carbide substrate 100 with at least one silicon carbide epitaxial layer 700 and a patterned layer having a plurality of silicon carbide regions coupling first reusable silicon carbide substrate 100 to the at least one silicon carbide epitaxial layer 700 wherein patterned layer comprises a second material and wherein a laser 2030 is configured to heat the second material such that the plurality of silicon carbide regions in patterned layer 700 are vaporized or partially vaporized. In one embodiment, patterned layer comprises patterned carbon 600. In one embodiment, the second material that forms a patterned layer comprises tantalum carbide.

In one embodiment, the exfoliation process wherein one or more devices are formed on or in the at least one silicon carbide epitaxial layer 700 and wherein the laser 2030 can couple through the at least one silicon carbide epitaxial layer 700 or the reusable silicon carbide substrate 100 to heat the second material of the patterned layer.

In one embodiment, the exfoliation process wherein a torque is applied to at least one of the reusable silicon carbide substrate 100 or the at least one silicon carbide epitaxial layer 700 to separate reusable silicon carbide substrate 100 from the at least one silicon carbide epitaxial layer 700 after the plurality of silicon carbide regions are vaporized or partially vaporized.

In one embodiment, the exfoliation process wherein a pulling force can be applied to the at least one of the reusable silicon carbide substrate 100 or the at least one silicon carbide epitaxial layer 700 to support the exfoliation process.

In one embodiment, the exfoliation process wherein the reusable silicon carbide substrate 100 is separated from the at least one silicon carbide epitaxial layer 700 and wherein reusable silicon carbide substrate 100 is prepared for reuse.

In one embodiment, the exfoliation process wherein each silicon carbide region of the plurality of silicon carbide regions in the patterned layer 600 is adjacent to the second material of the patterned layer.

In one embodiment, the exfoliation process wherein the second material comprises carbon.

In one embodiment, the exfoliation process wherein the at least one silicon carbide epitaxial layer 700 and the plurality of silicon carbide regions of the patterned layer are formed by merged epitaxial layer overgrowth on the reusable silicon carbide substrate 100 and wherein the at least one silicon carbide epitaxial layer 700 has a crystal orientation identical to the first reusable silicon carbide substrate.

In one embodiment, an exfoliation process for separating a reusable silicon carbide substrate 100 from at least one silicon carbide epitaxial layer 700 grown by merged epitaxial layer overgrowth (MELO) on reusable silicon carbide substrate 700 comprising a patterned layer between reusable silicon carbide substrate 100 and the at least one silicon carbide epitaxial layer 700 wherein a plurality of silicon carbide pillars 710 are formed in patterned layer when at least one silicon carbide epitaxial layer 700 is formed, wherein a laser 2030 is configured to heat a material in patterned layer such that the plurality of silicon carbide pillars 710 are vaporized or partially vaporized during the exfoliation process, and wherein a torque is applied to at least one silicon carbide epitaxial layer 700 or reusable silicon carbide substrate 100 to separate at least one silicon carbide epitaxial layer 700 from reusable silicon carbide substrate 100.

In one embodiment, the exfoliation process wherein the laser 2030 has a wavelength in a range of 532 nanometers, 1064 nanometers, 623-700 nanometers, or 632 nanometers.

In one embodiment, the exfoliation process wherein the laser 2030 is pulsed or continuous wave.

In one embodiment, the exfoliation process wherein the material in the patterned layer is carbon.

In one embodiment, the exfoliation process wherein the laser 2030 is configured to heat the carbon in the patterned layer greater than 3000 degrees Celsius.

In one embodiment, the exfoliation process wherein the heat from the carbon is configured to drop by more than 3000 degrees Celsius within ten microns of the at least one silicon carbide epitaxial layer 700 and wherein at least one silicon carbide epitaxial layer 700 has a thickness greater than ten microns.

In one embodiment, the exfoliation process wherein a pulling force can be applied to the at least one of the reusable silicon carbide substrate 100 or the at least one silicon carbide epitaxial layer 700 to support the exfoliation process.

In one embodiment, a exfoliation process for separating substrates comprising a reusable silicon carbide substrate 100, a patterned layer of carbon in or overlying a surface of reusable silicon carbide substrate 100, at least one silicon carbide epitaxial layer 700 formed overlying patterned layer of carbon wherein a plurality of silicon carbide regions in patterned layer couple between reusable silicon carbide substrate 100 and at least one silicon carbide epitaxial layer 700 and wherein at least one epitaxial layer 700 has a crystal orientation of reusable silicon carbide substrate 100.

In one embodiment, the exfoliation process wherein patterned layer 600 of carbon comprises a plurality of trenches 1100 configured to be formed in reusable silicon carbide substrate 100 and a plurality of microvoids 1110 configured to be formed underlying plurality of trenches 1100 wherein adjacent microvoids of plurality of microvoids 1110 do not couple together thereby forming the patterned layer, wherein plurality of microvoids 1110 are configured to be filled or to be partially filled with a polymer and pyrolyzed to carbon 1200, and wherein silicon carbide between plurality of microvoids 1110 comprises the plurality of silicon carbide regions in patterned layer.

In one embodiment, the exfoliation process wherein the patterned layer of carbon comprises a layer of carbon 1200 deposited on the reusable silicon carbide substrate 100 and patterned by a photolithographic process wherein a merged epitaxial layer overgrowth process is configured to grow silicon carbide on exposed areas of the surface of the reusable silicon carbide substrate 100 through the patterned layer and form the at least one silicon carbide epitaxial layer 1300 and wherein the silicon carbide grown on the exposed areas of the surface of the reusable silicon carbide substrate 100 comprises the plurality of silicon carbide regions.

In one embodiment, the exfoliation process wherein a laser 2030 is configured to heat the carbon 1200 in the patterned layer such that the plurality of silicon carbide regions in the patterned layer is vaporized or partially vaporized.

In one embodiment, the exfoliation process wherein on or more devices 1950 are formed in or on the at least one silicon carbide epitaxial layer 700, wherein a torque is applied to at least one silicon carbide epitaxial layer 700 or the reusable silicon carbide substrate 100 to separate at least one silicon carbide epitaxial layer 700 from reusable silicon carbide substrate 700, wherein the patterned layer is configured to release under the shear force applied by the torque, and wherein the separated reusable silicon carbide substrate 2230 can be prepared and used in another exfoliation process.

In one embodiment, the exfoliation can be initiated using the laser prior to device fabrication with the Epitaxial layer attached to the substrate on the edges. Once the front side device fabrication is completed, the handle layer is attached and the edges can be released using a UV laser and the full exfoliation can be completed (please use the right language with the appropriate reference to the figures).

In one embodiment, an entire new thick substrate, from 100 microns to 400 Microns can be grown over the substrate with the release layer with carbon voids and then separated using the process described above. The approach to such growth can be Epitaxial growth following merged Epitaxial overgrowth or high temperature Chemical vapor deposition or physical vapor transport.

In one embodiment, a method of forming a silicon carbide wafer comprises providing a reusable silicon carbide substrate 3100, forming a patterned layer 3500, comprising a heatable material 3610, growing a plurality of epitaxial layers to form an epitaxial silicon carbide substrate 4020, and heating the heatable material 3610 in the patterned layer 3500 to support separation of the reusable silicon carbide substrate 3100 from the epitaxial silicon carbide substrate 4020

In one embodiment, a method of forming a silicon carbide wafer further includes preparing a surface of the reusable silicon carbide substrate 3100 by chemical mechanical planarization (CMP), and reusing the reusable silicon carbide substrate 3100 for forming another epitaxial silicon carbide substrate 4020 or forming a plurality of semiconductor devices 4200 on or overlying the reusable silicon carbide substrate 3100.

In one embodiment, a method of forming a silicon carbide wafer wherein the epitaxial silicon carbide substrate 4020 has a mechanical strength to support standard silicon carbide wafer processing and handling.

In one embodiment, a method of forming a silicon carbide wafer wherein patterned layer 3500 comprises etching a pattern 3410 in the reusable silicon carbide substrate 3100, forming a layer of the heatable material 3610 within etched regions of the pattern 3410, and forming a protective layer 3620 overlying the heatable material 3610.

In one embodiment, the method of forming a silicon carbide wafer further includes etching the pattern 3410 as a plurality of pillars in the reusable silicon carbide substrate 3100 wherein adjacent pillars of the plurality of pillars have a predetermined spacing 3520 and forming the layer of the heatable material 3610 and the protective layer 3620 in the patterned layer 3500 having a height 3510 less than a height of the plurality of pillars.

In one embodiment, the method of forming a silicon carbide wafer further includes using one or more lasers to heat the heatable material 3610 such that the heat produces a thermal shock to the patterned layer 3500 that fractures, weakens, or stresses the plurality of pillars along a plane of the patterned layer 3500, and applying a force or torque to support separation of the reusable silicon carbide substrate 3100 from the epitaxial silicon carbide substrate 4020.

In one embodiment, the method of forming a silicon carbide wafer wherein the heatable material 3610 comprises carbon, tantalum carbide, or parylene and wherein the protective layer 3620 comprises tantalum carbide.

In one embodiment, the method of forming a silicon carbide wafer further includes growing a first silicon carbide epitaxial layer 3700 overlying the patterned layer 3500 wherein the first silicon carbide epitaxial layer 3700 is formed by epitaxial lateral overgrowth and wherein the first silicon carbide epitaxial layer 3700 forms a contiguous surface overlying the patterned layer, growing one or more silicon carbide epitaxial layers 3900 overlying the first epitaxial layer 3700 by epitaxial vertical overgrowth, wherein the first silicon carbide epitaxial layer 3700 and the one or more silicon carbide epitaxial layers 3900 comprise the epitaxial silicon carbide substrate 4020, and wherein the epitaxial silicon carbide substrate 4020 has a crystal orientation identical to the reuseable silicon carbide substrate 3100, and preparing one or more surfaces of the epitaxial silicon carbide substrate 4020 for standard wafer processing after separation from the reuseable silicon carbide substrate 3100.

In one embodiment, the method of forming a silicon carbide wafer wherein the reuseable silicon carbide substrate 3100 comprises a silicon carbide epitaxial layer 3700 formed by lateral epitaxial overgrowth and one or more silicon carbide epitaxial layers 3900 formed by epitaxial vertical lateral overgrowth and wherein a surface of the reuseable silicon carbide substrate 3100 comprises epitaxial lateral overgrowth.

In one embodiment, the method of forming a silicon carbide wafer further includes providing the prepared epitaxial silicon carbide substrate for semiconductor wafer manufacturing, forming a plurality of semiconductor devices 4200 on the prepared epitaxial silicon carbide substrate such as power transistors, integrated circuits, waveguides, passive components, or micro electro-mechanical systems, and dicing the plurality of semiconductor devices into individual die.

In one embodiment, the method of forming a silicon carbide wafer further includes preparing the contiguous surface of the first silicon carbide epitaxial layer 4700 having a Si-face (Silicon face) prior to forming the one or more silicon carbide epitaxial layers 4800, preparing an exposed surface of the first silicon carbide epitaxial layer 4700 after the separation having a C-face (Carbon face), and forming the plurality of semiconductor devices 5300 on the C-face of the first silicon carbide epitaxial layer 4700.

In one embodiment, the method of forming a silicon carbide wafer further includes growing a first silicon carbide epitaxial layer 4700 overlying the patterned layer 4610 wherein the first silicon carbide epitaxial layer 4700 is formed by epitaxial lateral overgrowth and wherein the first silicon carbide epitaxial layer 4700 forms a contiguous surface overlying the patterned layer 4610, growing a second silicon carbide epitaxial layer 4800 overlying the first silicon carbide epitaxial layer 4700 by epitaxial vertical overgrowth, depositing a layer of poly silicon carbide coating to the second silicon carbide epitaxial layer 4800 or bonding a poly silicon carbide wafer to the second silicon carbide epitaxial layer 4800, preparing an exposed surface of the first silicon carbide epitaxial layer 4700 after the separation having a C-face (Carbon face), forming a plurality of semiconductor devices 5300 on the prepared exposed surface of the epitaxial silicon carbide substrate 5020 such as power transistors, integrated circuits, waveguides, passive components, or micro electro-mechanical systems, and dicing the plurality of semiconductor devices into individual die.

In one embodiment, a method of forming a silicon carbide wafer comprises providing a reusable silicon carbide substrate 3100 wherein the reuseable silicon carbide substrate 3100 comprises a plurality of epitaxial layers, forming a patterned layer 3500 comprising a heatable material 3610 in the reuseable silicon carbide substrate 3100, growing a plurality of epitaxial layers overlying the patterned layer 3500 to form an epitaxial silicon carbide substrate 4020, and heating the patterned layer 3500 to support separation of the reusable silicon carbide substrate 3100 from the epitaxial silicon carbide substrate 4020.

In one embodiment, a method of forming a silicon carbide wafer further includes etching a plurality of trenches in the reuseable silicon carbide substrate 3100 to form the patterned layer 3500, forming a layer of the heatable material 3610 in the plurality of trenches, forming a protective layer 3620 overlying the heatable material 3610, growing a first silicon carbide epitaxial layer 3700 by epitaxial lateral overgrowth overlying the plurality of trenches to form a contiguous surface, and growing one or more silicon carbide epitaxial layers 3900 overlying the first silicon carbide epitaxial layer 3700 wherein the first silicon carbide epitaxial layer 3700 and the one or more silicon carbide epitaxial layers 3900 has a mechanical strength to support standard silicon carbide wafer processing and handling.

In one embodiment, a method of forming a silicon carbide wafer wherein the plurality of trenches form a plurality of pillars, wherein adjacent pillars and wherein the layer of heatable material 3610 is less than a height 3510 of the each pillar of the plurality of pillars.

In one embodiment, a method of forming a silicon carbide wafer wherein the layer of heatable material 3610 comprises carbon, tantalum carbide, or parylene and wherein one or more lasers are configured to heat the layer of heatable material 3610 to produce a thermal shock to the patterned layer 3500 that fractures, weakens, or stresses the pattern layer along a plane of the patterned layer 3500 such that the reuseable silicon carbide substrate 3100 can be separated from the epitaxial silicon carbide substrate 4020.

In one embodiment, a method of forming a silicon carbide wafer further includes preparing an exposed surface of the first silicon carbide epitaxial layer 4700 after separation wherein the patterned layer 4610 is removed and wherein a surface of the first silicon carbide epitaxial layer 4700 undergoes chemical mechanical planarization (CMP) having a C-face (Carbon-face), and forming the plurality of semiconductor devices 5300 on the C-face of the first silicon carbide epitaxial layer 4700.

In one embodiment, a method of forming a silicon carbide wafer further includes preparing a surface of the reuseable silicon carbide substrate 4600 for reuse.

In one embodiment, a method of forming silicon carbide wafers comprises a plurality of reusable silicon carbide substrates 3100 wherein the reuseable silicon carbide substrate 3100 comprises a plurality of epitaxial layers wherein each reuseable silicon carbide substrate 3100 includes a patterned layer 3500 comprising a heatable material 3610 configured to produce a thermal shock to the patterned layer 3500 when heated that fractures, weakens, or stresses the patterned layer 3500 along a plane of the patterned layer 3500, placing the plurality of reusable silicon carbide substrates 3100 in a silicon carbide epitaxial reactor capable of batch mode operation, growing a first silicon carbide epitaxial layer 3700 overlying the patterned layer 3500 having a contiguous surface on each substrate of the plurality of reusable silicon carbide substrates 3100 in the silicon carbide epitaxial reactor wherein the first silicon carbide epitaxial layer 3700 is grown by epitaxial lateral overgrowth, growing at least one silicon carbide epitaxial layer 3900 overlying the first silicon carbide epitaxial 3700 layer of each substrate of the plurality of reuseable silicon carbide substrate 3100 in the silicon carbide epitaxial reactor wherein the at least one silicon carbide epitaxial layer 3900 is grown by epitaxial vertical overgrowth and wherein the first silicon carbide epitaxial layer 3700 and the at least one silicon carbide epitaxial layer 3900 comprises an epitaxial silicon carbide substrate 4020, removing the plurality of reuseable silicon carbide substrates 3100 from the silicon carbide epitaxial reactor, heating the patterned layer 3500 of each reuseable silicon carbide substrate 3100 of the plurality of reuseable silicon carbide substrates 3100 using one or more lasers, separating each epitaxial silicon carbide substrate 4020 from each reusable silicon carbide substrate 3100 of the plurality of reuseable silicon carbide substrates 3100, preparing at least one surface of each epitaxial silicon carbide substrate 4020 for use in a manufacture of silicon carbide devices, and preparing at least one surface of each reuseable silicon carbide substrate 3100 for reuse in a manufacture of epitaxial silicon carbide substrates 4020.

What is claimed is:

1. A repeatable method of forming two semiconductor wafers from a single reuseable semiconductor wafer and using the two semiconductor wafers for wafer processing or to generate new wafers, the method comprising:
etching a plurality of trenches in a surface of a silicon carbide (SiC) substrate;
forming a heatable layer in the plurality of trenches;
forming a protective layer overlying the heatable layer in the plurality of trenches, wherein a patterned layer comprises the heatable layer, the protective layer, and the plurality of trenches;
growing an epitaxial layer overlying the patterned layer using epitaxial lateral overgrowth;
growing one or more epitaxial layers overlying the epitaxial layer by vertical epitaxial overgrowth;
heating the heatable material to produce a thermal shock that fractures or weakens the patterned layer;
separating the one or more epitaxial layers from the SiC substrate wherein a portion of the patterned layer and the epitaxial layer is coupled to the one or more epitaxial layers, wherein a remaining portion of the patterned layer is coupled to the SiC substrate, and wherein a SiC epitaxial substrate comprises the portion of the patterned layer, the epitaxial layer, and the one or more epitaxial layers;
polishing a surface of the portion of the patterned layer of the SiC epitaxial substrate; and
removing the remaining portion of the patterned layer from the separated SiC substrate to expose a surface of the separated SiC substrate, wherein the surface of the separated SiC substrate is polished and planarized.

2. The method of claim 1 further including forming semiconductor devices in or overlying a surface of the one or more epitaxial layers of the epitaxial substrate.

3. The method of claim 1 further including using the SiC epitaxial substrate in the repeatable method.

4. The method of claim 1 further including using the separated SiC substrate in the repeatable method.

5. The method of claim 4 wherein the SiC substrate comprises one or more epitaxial layers.

6. The method of claim 1 wherein the silicon carbide substrate is cut from a silicon carbide boule.

7. The method of claim 1 wherein the heatable layer is a carbon layer.

8. The method of claim 7 wherein the plurality of trenches form a plurality of pillars in the patterned layer, wherein the protective layer is a tantalum carbide layer, and wherein the carbon layer and the tantalum carbide layer are below a surface of each pillar of the plurality of pillars.

9. The method of claim 1 further including polishing a surface of the one or more epitaxial layers.

10. The method of claim 1 further including heating the heatable layer with one or more lasers.

11. The method of claim 1 further including applying a torque, pulling force, or both to the one or more epitaxial layers or the SiC substrate to support separation.

12. A repeatable method of forming two semiconductor wafers from a single reuseable semiconductor wafer and using the two semiconductor wafers for wafer processing or to generate new wafers, the method comprising:
etching a plurality of trenches in a surface of a silicon carbide (SiC) substrate to form a plurality of pillars wherein the plurality of pillars;
depositing a heatable material in the plurality of trenches;
depositing a protective material overlying the heatable material in the plurality of trenches, wherein the heatable material and the protective material are below a surface of each pillar of the plurality of pillars and wherein the heatable material, the protective material, and the plurality of pillars comprise a patterned layer;
growing an epitaxial layer overlying the patterned layer using epitaxial lateral overgrowth;
growing one or more epitaxial layers overlying the epitaxial layer by vertical epitaxial overgrowth;
polishing a surface of the one or more epitaxial layers;
heating the heatable material to produce a thermal shock that fractures or weakens the patterned layer;
separating the one or more epitaxial layers from the SiC substrate along a plane of the patterned layer, wherein a portion of the patterned layer and the epitaxial layer is coupled to the one or more epitaxial layers, wherein the portion of the patterned layer, the epitaxial layer, and the one or more epitaxial layers comprise a SiC epitaxial substrate, and wherein a remaining portion of the patterned layer is coupled to the SiC substrate;
removing the remaining portion of the patterned layer from the separated SiC substrate to expose a surface of the separated SiC substrate, wherein the surface of the separated SiC substrate is polished and planarized; and
polishing a surface of the portion of the patterned layer on the SiC epitaxial substrate.

13. The method of claim 12 wherein lateral fronts of epitaxial regions of the epitaxial layer merge due to epitaxial lateral overgrowth.

14. The method of claim 12 further including reusing the separated SiC substrate in the repeatable method.

15. The method of claim 12 further including forming a plurality of semiconductor devices or circuits in the SiC epitaxial substrate.

16. The method of claim 12 further including using the SiC epitaxial substrate in the repeatable method.

17. The method of claim 12 wherein the heatable material is carbon and wherein the protective material is tantalum carbide.

18. The method of claim 12 further including heating the heatable material with one or more lasers.

19. A repeatable method of forming two semiconductor wafers from a single reuseable semiconductor wafer and using the two semiconductor wafers for wafer processing or to generate new wafers, the method comprising:
forming a patterned layer that includes carbon overlying a SiC substrate;
growing an epitaxial layer using epitaxial lateral overgrowth overlying the patterned layer wherein the epitaxial layer merges to form a surface that overlies the SiC substrate;
growing at least one epitaxial layer using epitaxial vertical overgrowth overlying the epitaxial layer;
heating the carbon in the patterned layer with one or more lasers wherein the heat from the carbon produces a thermal shock that fractures or weakens the patterned layer;
separating the at least one epitaxial layer from the SiC substrate along a plane of the patterned layer, wherein a portion of the patterned layer and the epitaxial layer is coupled to the at least one epitaxial layer and wherein a remaining portion of the patterned layer is coupled to the SiC substrate;
removing the remaining portion of the patterned layer from the SiC substrate to expose a surface of the SiC substrate, wherein the surface of the SiC substrate is polished and planarized;
polishing a surface of the portion of the patterned layer on the at least one epitaxial layer; and
reusing the SiC substrate in the repeatable method.

20. The methodof claim 19 further including:
etching a plurality of trenches to form a plurality of pillars overlying the SiC substrate;
forming a carbon layer in the plurality of trenches; and
forming a tantalum carbide layer overlying the carbon layer in the plurality of trenches, wherein the plurality of pillars, the carbon layer, and the tantalum carbide layer comprise the patterned layer, and wherein the tantalum carbide layer is below a surface of the plurality of pillars such that lateral fronts of epitaxial regions of the epitaxial layer merge due to epitaxial lateral overgrowth.
